(19) United States
(12) Patent Application Publication
(10) Pub. No.: US 2026/0293104 A1
(43) Pub. Date: Sep. 24, 2026

(54) SEMICONDUCTOR DEVICE AND SEMICONDUCTOR STORAGE DEVICE

(71) Applicant: Kioxia Corporation, Tokyo (JP)

(72) Inventors: Tomoki ITO, Yokkaichi Mie (JP); Yurika SERIZAWA, Yokkaichi Mie (JP); Takuya KIKUCHI, Yokkaichi Mie (JP); Yusuke MUTO, Yokkaichi Mie (JP); Akifumi GAWASE, Kuwana Mie (JP)

(73) Assignee: Kioxia Corporation, Tokyo (JP)

(21) Appl. No.: 19/325,586

(22) Filed: Sep. 11, 2025

(30) Foreign Application Priority Data
Mar. 24, 2025 (JP) 2025-048398

(51) Int. Cl. H10B 12/00

(52) U.S. Cl. CPC H10B 12/33

(57) ABSTRACT

A semiconductor device includes a first electrode, a second electrode, an oxide semiconductor layer between the first and second electrodes, a gate electrode on the oxide semiconductor layer, a gate insulating layer between the gate electrode and the oxide semiconductor layer, a conductive layer in contact with the second electrode, a first insulating layer on the gate electrode, a second insulating layer on another side of the gate electrode and between a third insulating layer and the gate electrode, the second electrode includes a metal nitride layer in contact with the conductive layer and an oxide conductor layer between the metal nitride layer and the oxide semiconductor layer and in contact with the oxide semiconductor layer, and the gate insulating layer surrounds the metal nitride layer in a first cross section passing through the metal nitride layer.

### CROSS-REFERENCE TO RELATED APPLICATION

This application is based upon and claims the benefit of priority from Japanese Patent Application No. 2025-048398, filed Mar. 24, 2025, the entire contents of which are incorporated herein by reference.

### FIELD

Embodiments described herein relate generally to a semiconductor device and a semiconductor storage device.

### BACKGROUND

An oxide semiconductor transistor with a channel formed in an oxide semiconductor layer has an excellent characteristic that the channel leak current in the off state is extremely low. Therefore, the oxide semiconductor transistor can be used as a switching transistor for a memory cell of a dynamic random access memory (DRAM), for example.

### BRIEF DESCRIPTION OF THE DRAWINGS

FIG. 1 is a schematic diagram showing a semiconductor device according to a first embodiment.

FIG. 2 is a schematic diagram showing the semiconductor device according to the first embodiment.

FIG. 3 is a schematic diagram showing the semiconductor device according to the first embodiment.

FIG. 4 is a schematic diagram showing the semiconductor device according to the first embodiment.

FIG. 5 is a schematic diagram showing a semiconductor device according to a first comparative example.

FIG. 6 is a diagram for illustrating a problem with the semiconductor device according to the first comparative example.

FIG. 7 is a diagram for illustrating an operation and an effect of the semiconductor device according to the first embodiment.

FIG. 8 is a schematic diagram showing a semiconductor device according to a second comparative example.

FIG. 9 is a schematic diagram showing a semiconductor device according to a variation of the first embodiment.

FIG. 10 is a schematic diagram showing a semiconductor device according to a second embodiment.

FIG. 11 is a schematic diagram showing a semiconductor device according to a variation of the second embodiment.

FIG. 12 is a schematic diagram showing a semiconductor device according to a third embodiment.

FIG. 13 is a schematic diagram showing a semiconductor device according to a fourth embodiment.

FIG. 14 is a schematic diagram showing the semiconductor device according to the fourth embodiment.

FIG. 15 is a schematic diagram showing a semiconductor device according to a fifth embodiment.

FIG. 16 is a schematic diagram showing the semiconductor device according to the fifth embodiment.

FIG. 17 is a schematic diagram showing the semiconductor device according to the fifth embodiment.

FIG. 18 is a diagram for illustrating an operation and an effect of the semiconductor device according to the fifth embodiment.

FIG. 19 is a schematic diagram showing a semiconductor device according to a sixth embodiment.

FIG. 20 is a schematic diagram showing the semiconductor device according to the sixth embodiment.

FIG. 21 is a diagram for illustrating an operation and an effect of the semiconductor device according to the sixth embodiment.

FIG. 22 is a schematic diagram showing a semiconductor device according to a seventh embodiment.

FIG. 23 is a schematic diagram showing the semiconductor device according to the seventh embodiment.

FIG. 24 is a schematic diagram showing a semiconductor device according to a variation of the seventh embodiment.

FIG. 25 is a schematic diagram showing a semiconductor device according to an eighth embodiment.

FIG. 26 is a schematic diagram showing a semiconductor device according to a ninth embodiment.

FIG. 27 is an equivalent circuit diagram showing a semiconductor storage device according to a tenth embodiment.

FIG. 28 is a schematic cross-sectional view of the semiconductor storage device according to the tenth embodiment.

### DETAILED DESCRIPTION

One or more embodiments may provide a semiconductor device with excellent transistor characteristics.

In general, according to one embodiment, a semiconductor device includes a first electrode, a second electrode, an oxide semiconductor layer provided between the first electrode and the second electrode, a gate electrode opposed to the oxide semiconductor layer, a gate insulating layer provided between the gate electrode and the oxide semiconductor layer, a conductive layer in contact with the second electrode, a first insulating layer provided on the gate electrode on a side facing the first electrode, a second insulating layer provided on the gate electrode on a side facing the second electrode, and a third insulating layer with the second insulating layer provided between the third insulating layer and the gate electrode, the second electrode includes a metal nitride layer in contact with the conductive layer and an oxide conductor layer that is provided between the metal nitride layer and the oxide semiconductor layer and is in contact with the oxide semiconductor layer, and the gate insulating layer surrounds the metal nitride layer in a first cross section that is perpendicular to a first direction, which is a direction from the first electrode to the second electrode, and includes the metal nitride layer.

In the following, embodiments will be described with reference to the drawings. Note that in the following description, the same or similar members are denoted by the same reference numerals, and descriptions of members already described may be omitted as required.

In this specification, terms “up”, “down”, “upper”, “lower”, “above”, and “below” may be used for the sake of convenience. The terms “up”, “down”, “upper”, “lower”, “above”, and “below” mean only relative positional relationships in the drawings and do not define any gravity-based positional relationship.

Qualitative analysis and quantitative analysis of the chemical compositions of members of semiconductor devices and semiconductor storage devices in this specification can be performed in secondary ion mass spectrometry (SIMS), energy dispersive X-ray spectroscopy (EDX), or Rutherford back-scattering spectroscopy (RBS). The thickness of members of semiconductor devices and semiconductor storage devices, the distances between the members, the grain size, and the like can be measured with a transmission electron microscope (TEM), for example. (First Embodiment)

A semiconductor device according to a first embodiment includes a first electrode, a second electrode, an oxide semiconductor layer provided between the first electrode and the second electrode, a gate electrode opposed to the oxide semiconductor layer, a gate insulating layer provided between the gate electrode and the oxide semiconductor layer, a conductive layer in contact with the second electrode, a first insulating layer provided on the gate electrode on a side facing the first electrode, a second insulating layer provided on the gate electrode on a side facing the second electrode, and a third insulating layer with the second insulating layer provided between the third insulating layer and the gate electrode. The second electrode includes a metal nitride layer in contact with the conductive layer and an oxide conductor layer that is provided between the metal nitride layer and the oxide semiconductor layer and is in contact with the oxide semiconductor layer, and the gate insulating layer surrounds the metal nitride layer in a first cross section that is perpendicular to a first direction, which is a direction from the first electrode to the second electrode, and includes the metal nitride layer.

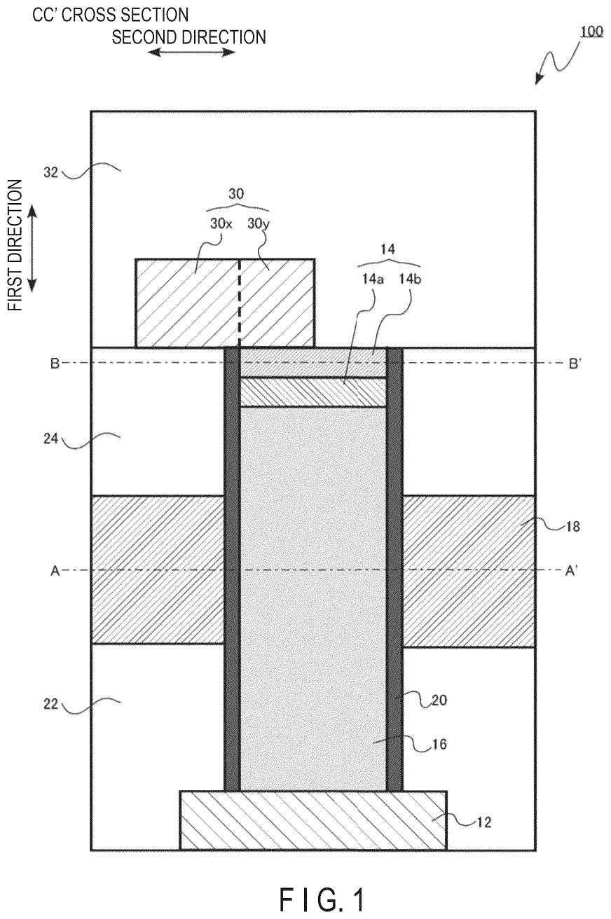

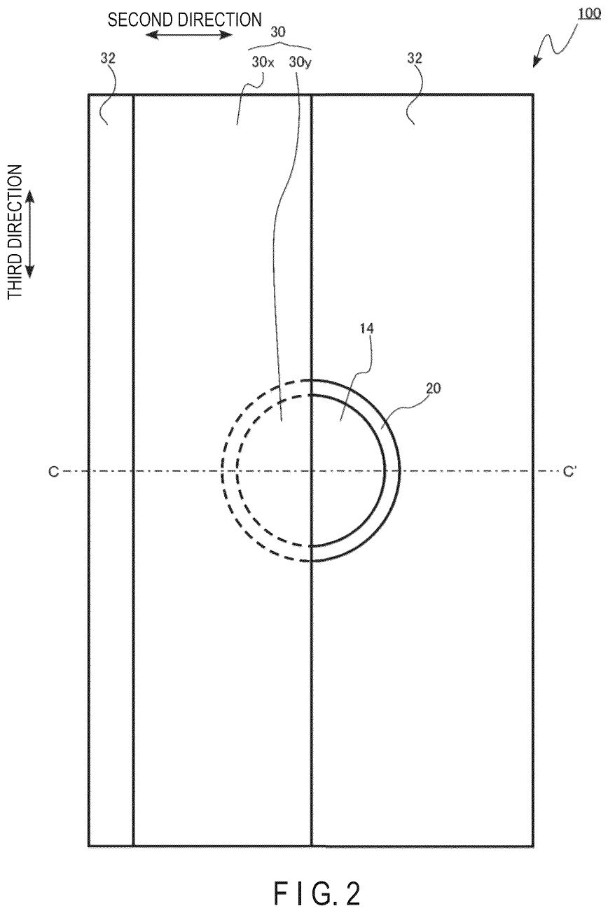

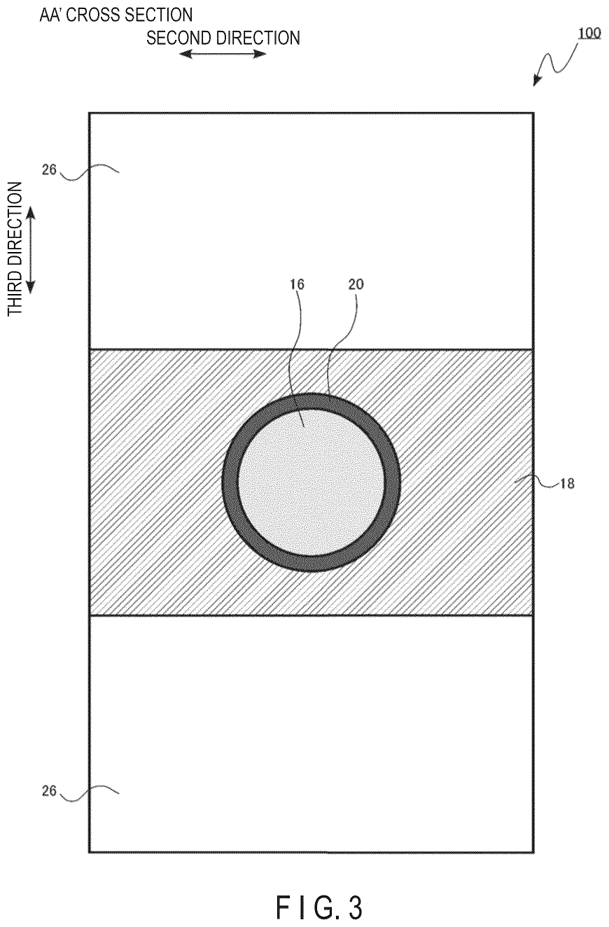

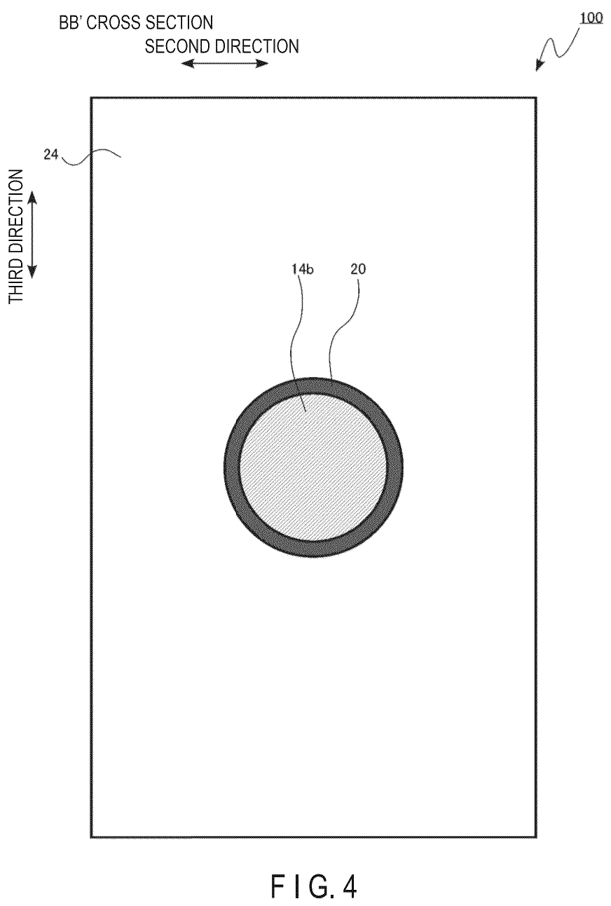

FIGS. 1, 2, 3, and 4 are schematic diagrams showing the semiconductor device according to the first embodiment. FIG. 2 is a top layout view of the semiconductor device in FIG. 1. FIG. 3 is a cross-sectional view taken along the line AA′ in FIG. 1 (AA′ cross section). FIG. 4 is a cross-sectional view taken along the line BB′ in FIG. 1 (BB′ cross section). FIG. 1 is a cross-sectional view taken along the line CC′ in FIG. 2 (CC′ cross section).

In FIG. 1, the up-and-down direction is referred to as the first direction. In FIG. 1, the left-and-right direction is referred to as a second direction. The second direction is perpendicular to the first direction. In FIG. 2, the up-and-down direction is referred to as a third direction. The third direction is perpendicular to the first direction and the second direction.

The AA′ cross section is an example of a second cross section. The BB′ cross section is an example of the first cross section.

The semiconductor device according to the first embodiment is a transistor 100. The transistor 100 is an oxide semiconductor transistor with a channel formed in an oxide semiconductor. In the transistor 100, a gate electrode is provided to surround an oxide semiconductor layer in which a channel is formed. The transistor 100 is a so-called gate all around transistor (GAA transistor). The transistor 100 is a so-called vertical transistor. Note that the gate electrode may be configured to be opposed to only a part of the oxide semiconductor layer.

The transistor 100 includes a lower electrode 12, an upper electrode 14, an oxide semiconductor layer 16, a gate electrode 18, a gate insulating layer 20, a lower insulating layer 22, an upper insulating layer 24, an intermediate insulating layer 26, a wiring layer 30, and an interlayer insulating layer 32. The upper electrode 14 includes an oxide conductor layer 14a and a metal nitride layer 14b. The wiring layer 30 includes a wiring part 30x and a contact part 30y.

The lower electrode 12 is an example of the first electrode. The upper electrode 14 is an example of the second electrode. The lower insulating layer 22 is an example of the first insulating layer. The upper insulating layer 24 is an example of the second insulating layer. The wiring layer 30 is an example of the conductive layer. The interlayer insulating layer 32 is an example of the third insulating layer.

The lower electrode 12 is provided under the oxide semiconductor layer 16. The lower electrode 12 is electrically connected to the oxide semiconductor layer 16. The lower electrode 12 is in contact with the oxide semiconductor layer 16, for example. The lower electrode 12 serves as a source electrode or a drain electrode of the transistor 100.

The lower electrode 12 is a conductor. The lower electrode 12 contains an oxide conductor, for example. The oxide conductor is a conductive metal oxide. For example, the lower electrode 12 contains oxygen (O) and one element selected from among the group consisting of tungsten (W), titanium (Ti), tantalum (Ta), molybdenum (Mo), copper (Cu), aluminum (Al), hafnium (Hf), gold (Au), platinum (Pt), palladium (Pd), ruthenium (Ru), yttrium (Y), vanadium (V), chromium (Cr), nickel (Ni), niobium (Nb), indium (In), gallium (Ga), zinc (Zn), and tin (Sb).

For example, the lower electrode 12 contains at least one conductor selected from among the group consisting of metal, metal nitride and metal carbide. For example, the lower electrode 12 contains one metal element selected from among the group consisting of tungsten (W), molybdenum (Mo), copper (Cu), aluminum (Al), titanium (Ti), and tantalum (Ta). For example, the lower electrode 12 contains nitrogen (N) and at least one metal element selected from among the group consisting of titanium (Ti), tungsten (W), molybdenum (Mo), and tantalum (Ta). For example, the lower electrode 12 contains titanium nitride, tungsten nitride, molybdenum nitride, or tantalum nitride. For example, the lower electrode 12 contains carbon (C) and at least one metal element selected from among the group consisting of titanium (Ti), tungsten (W), molybdenum (Mo), and tantalum (Ta). For example, the lower electrode 12 contains titanium carbide, tungsten carbide, molybdenum carbide, or tantalum carbide.

The lower electrode 12 may be a stack structure of two or more kinds of materials, for example. For example, the lower electrode 12 may be a stack structure of a metal nitride and an oxide conductor.

The upper electrode 14 is provided on the oxide semiconductor layer 16. The upper electrode 14 is electrically connected to the oxide semiconductor layer 16. For example, the upper electrode 14 is in contact with the oxide semiconductor layer 16. The upper electrode 14 serves as a source electrode or a drain electrode of the transistor 100.

The upper electrode 14 includes an oxide conductor layer 14a and a metal nitride layer 14b. The oxide conductor layer 14a is provided between the oxide semiconductor layer 16 and the metal nitride layer 14b. The metal nitride layer 14b is provided on the oxide conductor layer 14a.

A part of the upper electrode 14 is in contact with the interlayer insulating layer 32 in the first direction. A part of the metal nitride layer 14b is in contact with the interlayer insulating layer 32 in the first direction.

As shown in FIG. 4, in the first cross section that is, e.g., taken along a plane, perpendicular to the first direction and includes, e.g., passes through, the metal nitride layer 14b, the gate insulating layer 20 surrounds the metal nitride layer 14b. In the first cross section, the gate insulating layer 20 is in contact with the metal nitride layer 14b.

The oxide conductor layer 14a is in contact with the oxide semiconductor layer 16. The metal nitride layer 14b is in contact with the oxide conductor layer 14a.

The oxide conductor layer 14a is a conductor. The oxide conductor layer 14a contains an oxide conductor. For example, the oxide conductor layer 14a contains oxygen (O) and one element selected from among the group consisting of tungsten (W), titanium (Ti), tantalum (Ta), molybdenum (Mo), copper (Cu), aluminum (Al), hafnium (Hf), gold (Au), platinum (Pt), palladium (Pd), ruthenium (Ru), yttrium (Y), vanadium (V), chromium (Cr), nickel (Ni), niobium (Nb), indium (In), gallium (Ga), zinc (Zn), and tin (Sb). For example, the oxide conductor layer 14a contains indium (In), tin (Sn), and oxygen (O). For example, the oxide conductor layer 14a contains indium tin oxide. The oxide conductor layer 14a is an indium tin oxide layer, for example.

The metal nitride layer 14b is a conductor. For example, the metal nitride layer 14b contains nitrogen (N) and at least one metal element selected from among the group consisting of titanium (Ti), tungsten (W), molybdenum (Mo), and tantalum (Ta). For example, the metal nitride layer 14b contains titanium nitride, tungsten nitride, molybdenum nitride, or tantalum nitride. For example, the metal nitride layer 14b includes a titanium nitride layer, a tungsten nitride layer, a molybdenum nitride layer, or a tantalum nitride layer. For example, the metal nitride layer 14b is a titanium nitride layer.

The metal nitride layer 14b may be a stack structure of two or more kinds of metal nitrides, for example.

The oxide semiconductor layer 16 is provided between the lower electrode 12 and the upper electrode 14. The oxide semiconductor layer 16 is in contact with the lower electrode 12, for example. The oxide semiconductor layer 16 is in contact with the upper electrode 14, for example.

In the oxide semiconductor layer 16, a channel serving as a current path is formed when the transistor 100 is turned on.

The oxide semiconductor layer 16 is an oxide semiconductor. For example, the oxide semiconductor layer 16 is amorphous.

For example, the oxide semiconductor layer 16 contains oxygen (O) and at least one element selected from among the group consisting of indium (in), gallium (Ga), zinc (Zn), aluminum (Al), tin (Sn), titanium (Ti), silicon (Si), germanium (Ge), copper (Cu), arsenic (As), and tungsten (W). For example, the oxide semiconductor layer 16 contains indium (In), gallium (Ga), zinc (Zn), and oxygen (O). For example, the oxide semiconductor layer 16 contains indium gallium zinc oxide. For example, the oxide semiconductor layer 16 is an indium gallium zinc oxide layer.

The oxide semiconductor layer 16 includes an oxygen hole. The oxygen hole in the oxide semiconductor layer 16 serves as a donor.

The length of the oxide semiconductor layer 16 in the first direction is equal to or more than 50 nm and equal to or less than 200 nm, for example. The length of the oxide semiconductor layer 16 in the second direction is equal to or more than 10 nm and equal to or less than 100 nm, for example.

The first direction is a direction from the lower electrode 12 to the upper electrode 14. The second direction is a direction perpendicular to the first direction.

The gate electrode 18 is opposed to the oxide semiconductor layer 16, e.g., the gate electrode 18 may face or be adjacent to the oxide semiconductor layer 16. The gate electrode 18 is provided in such a manner that the position coordinate thereof in the first direction assumes a value between the position coordinates of the lower electrode 12 and the upper electrode 14 in the first direction.

As shown in FIG. 3, the gate electrode 18 surrounds the oxide semiconductor layer 16 in the second cross section perpendicular to the first direction. The gate electrode 18 is provided around the oxide semiconductor layer 16.

The gate electrode 18 is a conductor. For example, the gate electrode 18 is a metal, a metal compound or a semiconductor. For example, the gate electrode 18 contains tungsten (W). For example, the gate electrode 18 is a tungsten layer.

The length of the gate electrode 18 in the first direction is equal to or more than 10 nm and equal to or less than 100 nm, for example.

The gate insulating layer 20 is provided between the oxide semiconductor layer 16 and the gate electrode 18. In the second cross section perpendicular to the first direction, the gate insulating layer 20 surrounds the oxide semiconductor layer 16. The gate insulating layer 20 is provided between the lower electrode 12 and the upper electrode 14. For example, the gate insulating layer 20 is in contact with the lower electrode 12 and the upper electrode 14.

The gate insulating layer 20 contains silicon (Si) and oxygen (O), for example. The gate insulating layer 20 contains silicon (Si) and nitrogen (N), for example. The gate insulating layer 20 contains silicon (Si), oxygen (O), and nitrogen (N), for example. For example, the gate insulating layer 20 contains silicon oxide. For example, the gate insulating layer 20 contains silicon nitride. For example, the gate insulating layer 20 has a stack structure of a silicon oxide film and a silicon nitride film.

The thickness of the gate insulating layer 20 is equal to or more than 2 nm and equal to or less than 10 nm, for example.

The lower insulating layer 22 is provided on the gate electrode 18 on a side facing the lower electrode 12. The lower insulating layer 22 is provided between the lower electrode 12 and the gate electrode 18.

In a cross section perpendicular to the first direction, the lower insulating layer 22 surrounds the oxide semiconductor layer 16. In a plane perpendicular to the first direction, the lower insulating layer 22 surrounds the gate insulating layer 20.

The lower insulating layer 22 is an insulator. For example, the lower insulating layer 22 is an oxide, a nitride, or an oxynitride. For example, the lower insulating layer 22 contains silicon (Si) and oxygen (O). For example, the lower insulating layer 22 contains silicon oxide. For example, the lower insulating layer 22 is a silicon oxide layer.

The upper insulating layer 24 is provided on the gate electrode 18 on a side facing the upper electrode 14. The upper insulating layer 24 is provided on the gate electrode 18.

In a cross section perpendicular to the first direction, the upper insulating layer 24 surrounds the oxide semiconductor layer 16. In a plane perpendicular to the first direction, the upper insulating layer 24 surrounds the gate insulating layer 20.

The upper insulating layer 24 is an insulator. For example, the upper insulating layer 24 is an oxide, a nitride, or an oxynitride. For example, the upper insulating layer 24 contains silicon (Si) and oxygen (O). For example, the upper insulating layer 24 contains silicon oxide. For example, the upper insulating layer 24 is a silicon oxide layer. For example, the upper insulating layer 24 is amorphous.

The intermediate insulating layer 26 is provided between the lower insulating layer 22 and the upper insulating layer 24. As shown in FIG. 3, the intermediate insulating layer 26 is provided at sides of the gate electrode 18 in the third direction. The gate electrode 18 is provided between a part of the intermediate insulating layer 26 and another part of the intermediate insulating layer 26 in the third direction.

The intermediate insulating layer 26 is an insulator. For example, the intermediate insulating layer 26 is an oxide, a nitride, or an oxynitride. For example, the intermediate insulating layer 26 contains silicon (Si) and oxygen (O). For example, the intermediate insulating layer 26 contains silicon oxide. For example, the intermediate insulating layer 26 is a silicon oxide layer.

The wiring layer 30 is provided on the upper insulating layer 24. The wiring layer 30 is provided on the upper electrode 14.

As shown in FIG. 2, the wiring layer 30 extends in the third direction. As shown in FIG. 2, the wiring layer 30 is patterned to be in contact with only a part of an upper surface of the upper electrode 14.

When the transistor 100 is applied as a switching transistor of a memory cell of a DRAM, for example, the wiring layer 30 serves as a bit line of the DRAM. Since the bit line is patterned to be in contact with only a part, rather than the whole, of the upper surface of the upper electrode 14, for example, the degree of integration of the memory cells can be raised.

The wiring layer 30 includes the wiring part 30x and the contact part 30y. The wiring part 30x is in contact with the upper insulating layer 24 in the first direction. The contact part 30y is in contact with a part of the upper electrode 14 in the first direction. The contact part 30y is in contact with a part of the metal nitride layer 14b in the first direction.

The wiring layer 30 is a conductor. For example, the wiring layer 30 is a conductor formed by a metal or a metal compound. For example, the wiring layer 30 contains at least one conductor selected from among the group consisting of metal, metal nitride, and metal carbide. For example, the wiring layer 30 contains one metal element selected from among the group consisting of tungsten (W), molybdenum (Mo), copper (Cu), aluminum (Al), titanium (Ti), and tantalum (Ta). For example, the wiring layer 30 contains nitrogen (N) and at least one metal element selected from among the group consisting of titanium (Ti), tungsten (W), molybdenum (Mo), and tantalum (Ta). For example, the wiring layer 30 contains titanium nitride, tungsten nitride, molybdenum nitride, or tantalum nitride. For example, the wiring layer 30 contains carbon (C) and at least one metal element selected from among the group consisting of titanium (Ti), tungsten (W), molybdenum (Mo), and tantalum (Ta). For example, the wiring layer 30 contains titanium carbide, tungsten carbide, molybdenum carbide, or tantalum carbide.

The wiring layer 30 may be a stack structure of two or more kinds of materials, for example.

The wiring layer 30 is a tungsten layer, for example.

The wiring part 30x and the contact part 30y contain a same first material, for example. The first material contained in the wiring part 30x and the contact part 30y is polycrystalline, for example.

The grain size of the first material contained in the wiring part 30x is larger than the grain size of the first material contained in the contact part 30y, for example.

When the first material contained in the wiring part 30x is tungsten, for example, the grain size of the tungsten contained in the wiring part 30x is larger than the grain size of the tungsten contained in the contact part 30y.

The grain size of the first material contained in the wiring layer 30 can be measured in automated crystal orientation mapping TEM (ACOM-TEM), for example. For example, a slice of sample including the wiring layer 30 is irradiated with an electron beam with the irradiation area narrowed down to several nanometers, and patterns of diffraction in the direction of transmission by the crystals in the wiring layer 30 are obtained in a plane in succession, thereby obtaining information on crystal orientations distributed in the plane. A section in which the crystal orientations are aligned is regarded as one crystal grain, and the grain size can be derived by calculating the diameter of a circle corresponding to the circumference of the section.

For example, the magnitude relationship between the grain size of the wiring part 30x and the grain size of the contact part 30y is determined by comparing an average value of a plurality of grain sizes of the wiring part 30x and an average value of a plurality of grain sizes of the contact part 30y.

The interlayer insulating layer 32 is provided on the upper insulating layer 24. The interlayer insulating layer 32 is provided on the wiring layer 30. The interlayer insulating layer 32 is provided on the upper electrode 14.

In the first direction, the interlayer insulating layer 32 is in contact with the wiring part 30x of the wiring layer 30. In the first direction, the interlayer insulating layer 32 is in contact with a part of the upper electrode 14. In the first direction, the interlayer insulating layer 32 is in contact with a part of the metal nitride layer 14b.

The interlayer insulating layer 32 is provided at sides of the wiring layer 30 in the second direction. In the second direction, the interlayer insulating layer 32 is in contact with a side surface of the wiring layer 30.

The interlayer insulating layer 32 is an insulator. For example, the interlayer insulating layer 32 is an oxide, a nitride, or an oxynitride. For example, the interlayer insulating layer 32 contains silicon (Si) and oxygen (O). For example, the interlayer insulating layer 32 contains silicon oxide. For example, the interlayer insulating layer 32 is a silicon oxide layer.

Next, an operation and an effect of the semiconductor device according to the first embodiment will be described.

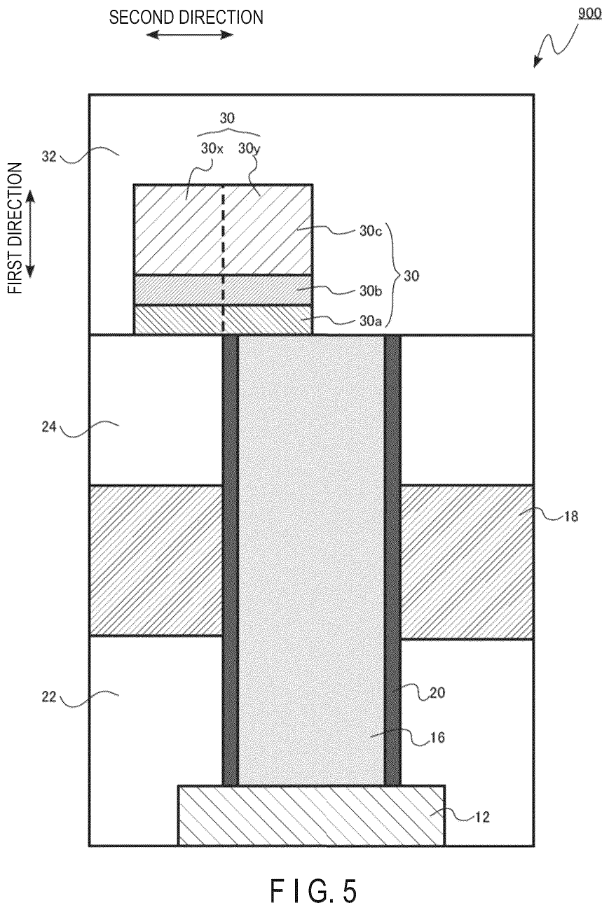

FIG. 5 is a schematic diagram showing a semiconductor device according to a first comparative example. FIG. 5 is a diagram corresponding to FIG. 1 showing the first embodiment.

The semiconductor device according to the first comparative example is a transistor 900. The transistor 900 differs from the transistor 100 according to the first embodiment in that the transistor 900 does not include the upper electrode 14. The transistor 900 also differs from the transistor 100 according to the first embodiment in that the wiring layer 30 has a stack structure of an oxide conductor film 30a, a metal nitride film 30b, and a metal film 30c.

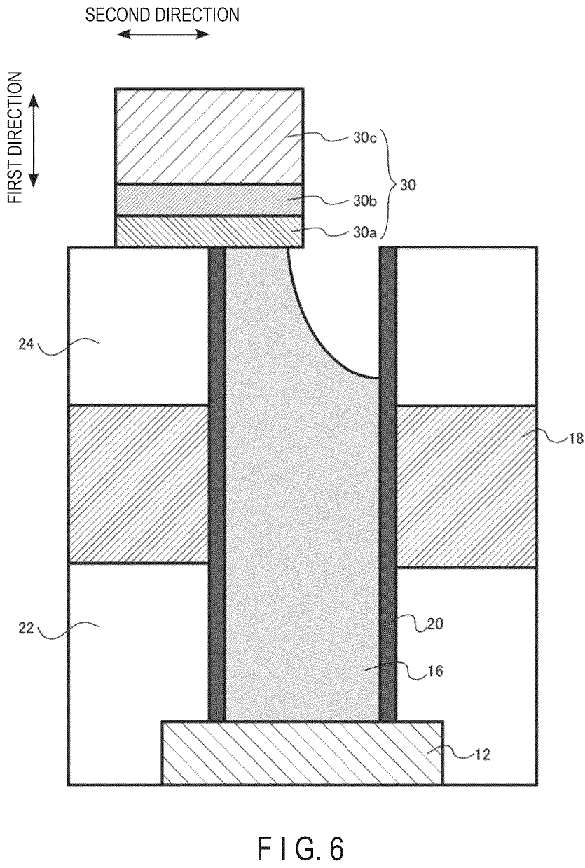

FIG. 6 is a diagram for illustrating a problem with the semiconductor device according to the first comparative example. FIG. 6 is a schematic cross-sectional view of the transistor 900 according to the first comparative example during production. FIG. 6 is a schematic cross-sectional view showing the transistor 900 after the wiring layer 30 is formed. FIG. 6 is a diagram corresponding to FIG. 5.

The wiring layer 30 is formed in a reactive ion etching process (RIE process), for example. After the wiring layer 30 is formed, for example, a post-etch treatment is performed using an acidic or alkaline chemical solution.

During production of the transistor 900 according to the first comparative example, a surface of the oxide semiconductor layer 16 is exposed when the wiring layer 30 is being formed, so that the oxide semiconductor layer 16 is etched by gas, ions, or radicals in the RIE. In addition, after the wiring layer 30 is formed, a surface of the oxide semiconductor layer 16 is exposed, so that the oxide semiconductor layer 16 is etched by the chemical solution in the post treatment. If the oxide semiconductor layer 16 is etched, the transistor characteristics of the transistor 900 deteriorates, for example.

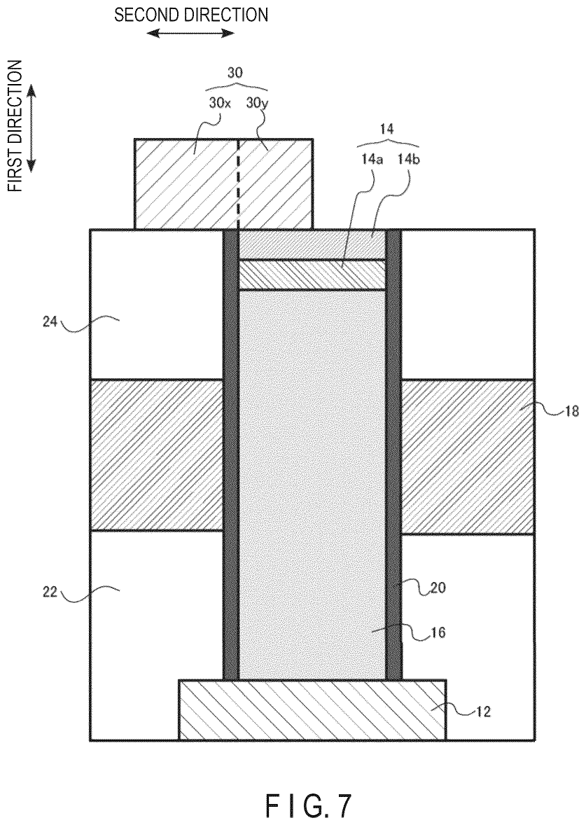

FIG. 7 is a diagram for illustrating an operation and an effect of the semiconductor device according to the first embodiment. FIG. 7 is a schematic cross-sectional view showing the transistor 100 according to the first embodiment during production. FIG. 7 is a schematic cross-sectional view showing the transistor 100 after the wiring layer 30 is formed. FIG. 7 is a diagram corresponding to FIG. 1.

In the transistor 100 according to the first embodiment, the upper electrode 14 is provided on the oxide semiconductor layer 16. Therefore, the surface of the oxide semiconductor layer 16 is not exposed after the wiring layer 30 is formed.

Therefore, the oxide semiconductor layer 16 is not etched when the wiring layer 30 is being formed or in the post treatment after the wiring layer 30 is formed. Therefore, the deterioration of the transistor characteristics of the transistor 100 is reduced.

In addition, in the transistor 900 according to the first comparative example, the upper surface of the oxide semiconductor layer 16 is in contact with the interlayer insulating layer 32. Therefore, for example, constituent elements of the oxide semiconductor layer 16 may diffuse into the interlayer insulating layer 32, and the chemical composition of the oxide semiconductor layer 16 may change. If the chemical composition of the oxide semiconductor layer 16 changes, the transistor characteristics of the transistor 900 change. In addition, constituent elements of the oxide semiconductor layer 16 may diffuse into the interlayer insulating layer 32, and the insulating properties of the interlayer insulating layer 32 may deteriorate. If the insulating properties of the interlayer insulating layer 32 deteriorate, a leak current occurs between adjacent wires or electrodes, and the transistor characteristics deteriorate.

In the transistor 100 according to the first embodiment, the upper electrode 14 is provided on the oxide semiconductor layer 16. Therefore, the upper surface of the oxide semiconductor layer 16 is not in contact with the interlayer insulating layer 32. Therefore, the diffusion of constituent elements of the oxide semiconductor layer 16 into the interlayer insulating layer 32 is prevented. Therefore, the change in the transistor characteristics of the transistor 100 is prevented.

The wiring layer 30 of the transistor 900 according to the first comparative example includes the wiring part 30x and the contact part 30y. The contact area between the oxide conductor film 30a of the contact part 30y of the wiring layer 30 and the oxide semiconductor layer 16 in the transistor 900 is substantially equal to the contact area between the contact part 30y of the wiring layer 30 and the metal nitride layer 14b in the transistor 100.

The contact resistance per unit area between an oxide conductor and an oxide semiconductor is greater than the contact resistance per unit area between a metal or metal compound and a metal nitride. Therefore, when the wiring layer 30 of the transistor 100 is made of a metal or metal compound, the electrical resistance between the wiring layer 30 and the oxide semiconductor layer 16 in the transistor 900 is greater than the electrical resistance between the wiring layer 30 and the oxide semiconductor layer 16 in the transistor 100.

Therefore, for example, the on resistance of the transistor 900 is greater than the on resistance of the transistor 100. In other words, the on resistance of the transistor 100 is smaller than the on resistance of the transistor 900, and the transistor characteristics are improved.

In the transistor 900, for example, it is assumed that the metal nitride film 30b is formed by titanium nitride, and the metal film 30c is formed by tungsten. The grain size of tungsten depends on the material of the layer under the layer of tungsten formed. The grain size of tungsten is smaller when the layer under the layer of tungsten is polycrystalline than when the layer under the layer of tungsten is amorphous.

In the transistor 900 according to the first comparative example, when the metal nitride film 30b is formed by titanium nitride and the metal film 30c is formed by tungsten, for example, the layer under the layer of tungsten in the wiring part 30x and the layer under the layer of tungsten in the contact part 30y are the same. Therefore, the grain size of the tungsten of the wiring part 30x and the grain size of the tungsten of the contact part 30y are substantially equal.

In addition, since titanium nitride tends to be polycrystalline, the grain size of the tungsten of the wiring part 30x and the grain size of the tungsten of the contact part 30y are relatively small. Since the grain size of the tungsten of the wiring part 30x and the grain size of the tungsten of the contact part 30y are relatively small, the electrical resistance of the wiring part 30x and the electrical resistance of the contact part 30y are high. Therefore, the electrical resistance of the wiring layer 30 is high, and there arises a problem of a signal delay of the transistor 900 due to the wiring layer 30, for example.

In the transistor 100 according to the first embodiment, when the metal nitride layer 14b is formed by titanium nitride, and the wiring layer is formed by tungsten, for example, the layer under the wiring part 30x is the upper insulating layer 24, and the layer under the contact part 30y is formed by titanium nitride. Since the layer under the wiring part 30x is formed by an amorphous insulator, the grain size of the tungsten of the wiring part 30x is larger than the grain size of the tungsten of the contact part 30y. Therefore, the electrical resistance of the wiring layer 30 decreases, and the signal delay of the transistor 100 due to the wiring layer 30 is reduced, for example.

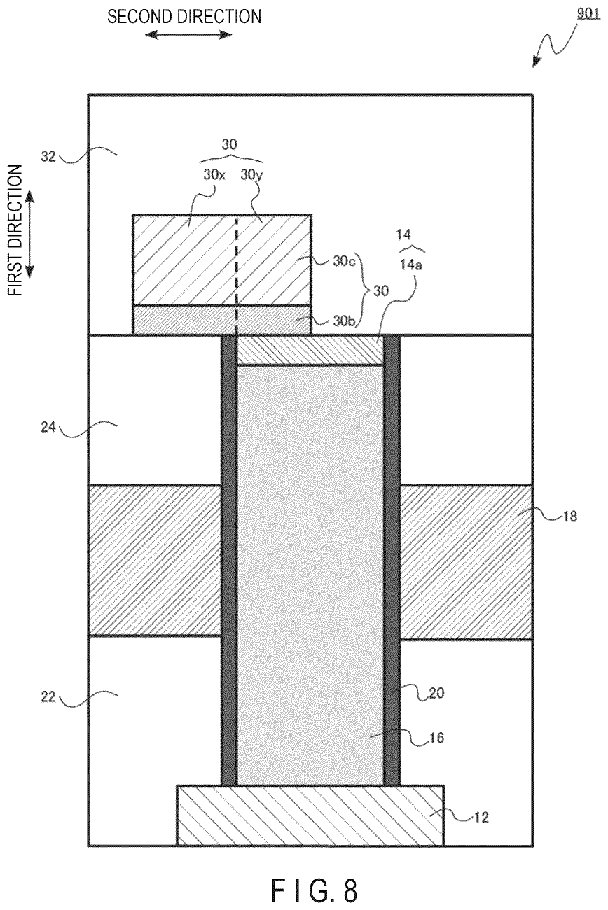

FIG. 8 is a schematic diagram showing a semiconductor device according to a second comparative example. FIG. 8 is a diagram corresponding to FIG. 1 showing the first embodiment.

The semiconductor device according to the second comparative example is a transistor 901. The transistor 901 differs from the transistor 100 according to the first embodiment in that the upper electrode 14 does not include the metal nitride layer 14b. The transistor 901 also differs from the transistor 100 according to the first embodiment in that the wiring layer 30 has a stack structure of a metal nitride film 30b and a metal film 30c.

The wiring layer 30 of the transistor 901 according to the second comparative example includes the wiring part 30x and the contact part 30y. The contact area between the metal nitride film 30b of the contact part 30y of the wiring layer 30 and the oxide conductor layer 14a in the transistor 901 is substantially equal to the contact area between the contact part 30y of the wiring layer 30 and the metal nitride layer 14b in the transistor 100.

Between a metal nitride and an oxide conductor, a metal oxide layer having a high resistance tends to be formed due to oxygen diffusion from the oxide conductor into the surface of the metal nitride. Therefore, the contact resistance per unit area between a metal nitride and an oxide conductor is greater than the contact resistance per unit area between a metal or metal compound and a metal nitride. Therefore, when the wiring layer 30 of the transistor 100 is made of a metal or metal compound, the electrical resistance between the wiring layer 30 and the oxide semiconductor layer 16 in the transistor 901 is greater than the electrical resistance between the wiring layer 30 and the oxide semiconductor layer 16 in the transistor 100.

Therefore, for example, the on resistance of the transistor 901 is greater than the on resistance of the transistor 100. In other words, the on resistance of the transistor 100 is lower than the on resistance of the transistor 901, and the transistor characteristics are improved.

In the transistor 901 according to the second comparative example, for example, when the metal nitride film 30b is formed by titanium nitride, and the metal film 30c is formed by tungsten, the layer under the layer of tungsten in the wiring part 30x and the layer under the layer of tungsten in the contact part 30y are the same. Therefore, the grain size of the tungsten of the wiring part 30x and the grain size of the tungsten of the contact part 30y are substantially equal.

In addition, since titanium nitride tends to be polycrystalline, the grain size of the tungsten of the wiring part 30x and the grain size of the tungsten of the contact part 30y in the transistor 901 are relatively small. Since the grain size of the tungsten of the wiring part 30x and the grain size of the tungsten of the contact part 30y are relatively small, the electrical resistance of the wiring part 30x and the electrical resistance of the contact part 30y are high. Therefore, the electrical resistance of the wiring layer 30 is high, and there arises a problem of a signal delay of the transistor 901 due to the wiring layer 30, for example.

In the transistor 100 according to the first embodiment, when the metal nitride layer 14b is formed by titanium nitride, and the wiring layer is formed by tungsten, for example, the layer under the wiring part 30x is the upper insulating layer 24, and the layer under the contact part 30y is formed by titanium nitride. Since the layer under the wiring part 30x is formed by an amorphous insulator, the grain size of the tungsten of the wiring part 30x is larger than the grain size of the tungsten of the contact part 30y. Therefore, the electrical resistance of the wiring layer 30 decreases, and the signal delay of the transistor 100 due to the wiring layer 30 is reduced, for example.

As described above, according to the first embodiment, a transistor 100 with excellent transistor characteristics can be provided which is reduced in deterioration of the transistor characteristics, has a decreased on resistance, and is reduced in signal delay due to the wiring layer.

### Variation

A semiconductor device according to a variation of the first embodiment differs from the semiconductor device according to the first embodiment in that the upper electrode is not in contact with the third insulating layer in the first direction.

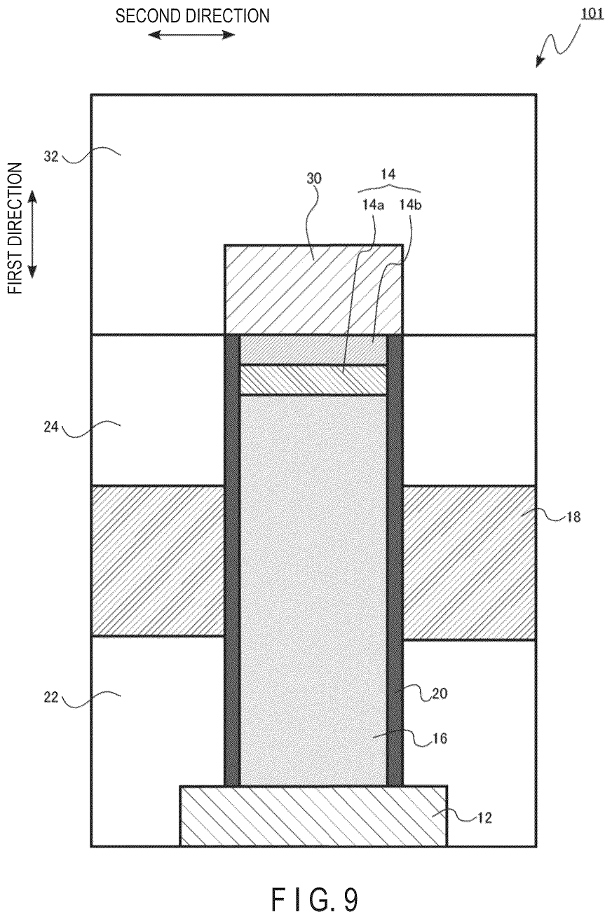

FIG. 9 is a schematic diagram showing the semiconductor device according to the variation of the first embodiment. FIG. 9 is a diagram corresponding to FIG. 1 showing the first embodiment.

The semiconductor device according to the variation of the first embodiment is a transistor 101. In the transistor 101, the upper electrode 14 is not in contact with the interlayer insulating layer 32 in the first direction. In the transistor 101, the wiring layer 30 is in contact with the whole of the upper surface of the upper electrode 14. Even if the wiring layer 30 is misaligned with the upper electrode 14 during production of the transistor 101, for example, the surface of the oxide semiconductor layer 16 is not exposed after the wiring layer 30 is formed, as in the production of the transistor 100 according to the first embodiment.

Therefore, as in the first embodiment, the oxide semiconductor layer 16 is not etched in the post treatment after the wiring layer 30 is formed. Therefore, deterioration of the transistor characteristics of the transistor 101 is reduced.

Thus, according to the variation of the first embodiment, a transistor 101 with excellent transistor characteristics can be provided which is reduced in deterioration of the transistor characteristics.

As described above, according to the first embodiment and the variation thereof, semiconductor devices with excellent transistor characteristics can be provided.

### Second Embodiment

A semiconductor device according to a second embodiment differs from the semiconductor device according to the first embodiment in that a metal nitride layer includes an amorphous region, and the region is in contact with a conductive layer. In the following, descriptions overlapping with the first embodiment may be omitted.

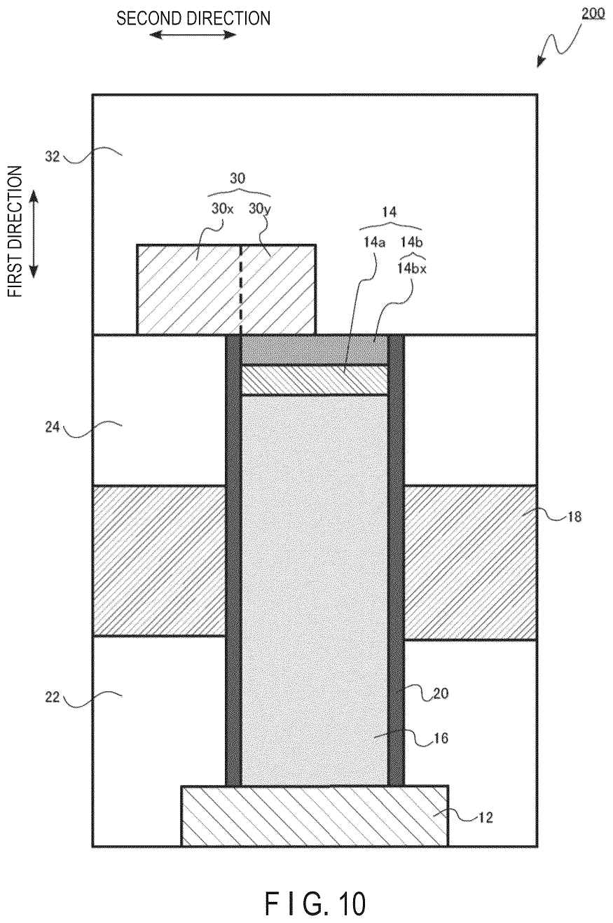

FIG. 10 is a schematic diagram showing the semiconductor device according to the second embodiment. FIG. 10 is a diagram corresponding to FIG. 1 showing the first embodiment.

The semiconductor device according to the second embodiment is a transistor 200. In the transistor 200, a metal nitride layer 14b of an upper electrode 14 includes an amorphous region 14bx. The amorphous region 14bx is an example of a region.

The amorphous region 14bx is amorphous. The amorphous region 14bx contains an amorphous metal nitride. For example, the amorphous region 14bx contains molybdenum nitride, tungsten nitride, or tantalum nitride.

The amorphous region 14bx can be formed by selecting an appropriate material and an appropriate formation condition.

In the transistor 200, when the wiring layer 30 is formed by tungsten, the layer under the wiring part 30x is the upper insulating layer 24, and the layer under the contact part 30y is the amorphous region 14bx. Therefore, not only the grain size of the tungsten of the wiring part 30x but also the grain size of the tungsten of the contact part 30y is large. Therefore, the electrical resistance of the wiring layer 30 decreases, and the signal delay of the transistor 200 due to the wiring layer 30 is reduced, for example.

Note that the amorphous region 14bx may be only a part of the metal nitride layer 14b. For example, the amorphous region 14bx may be only an upper part of the metal nitride layer 14b that comes into in contact with the wiring layer 30.

Note that whether the metal nitride layer 14b includes the amorphous region 14bx can be determined with a transmission electron microscope, for example.

As described above, according to the second embodiment, a transistor 200 with excellent transistor characteristics can be provided which is reduced in deterioration of the transistor characteristics, has a decreased on resistance, and is reduced in signal delay due to the wiring layer.

### Variation

In a semiconductor device according to a variation of the second embodiment, a metal nitride layer includes a first region and a second region having a chemical composition different from the chemical composition of the first region, the first region is provided between the second region and an oxide conductor layer, and the second region is amorphous and in contact with a conductive layer.

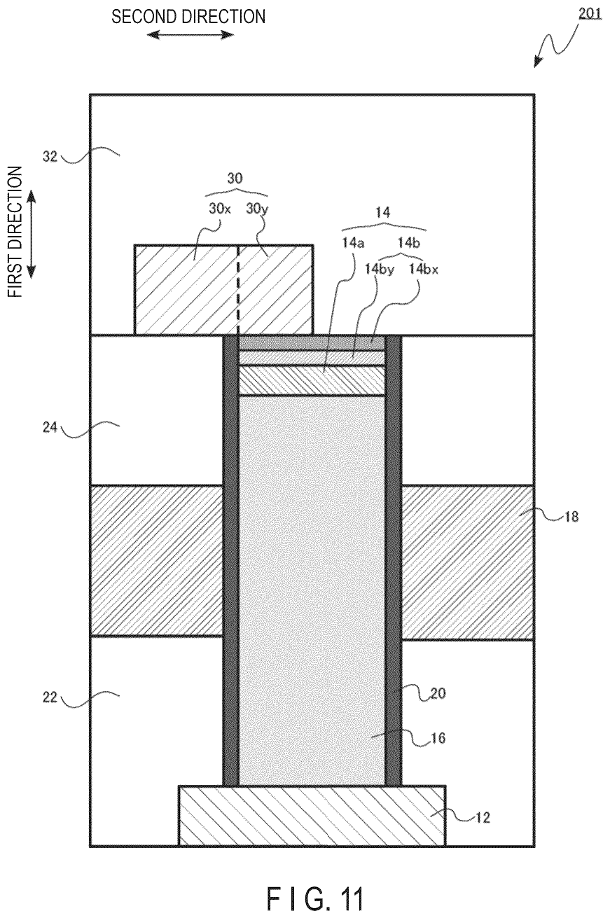

FIG. 11 is a schematic diagram showing the semiconductor device according to the variation of the second embodiment. FIG. 11 is a diagram corresponding to FIG. 10 showing the second embodiment.

The semiconductor device according to the variation of the second embodiment is a transistor 201. In the transistor 201, a metal nitride layer 14b includes a polycrystalline region 14by and an amorphous region 14bx.

The polycrystalline region 14by is an example of the first region. The amorphous region 14bx is an example of the second region.

The polycrystalline region 14by is provided between the amorphous region 14bx and an oxide conductor layer 14a.

The polycrystalline region 14by is polycrystalline. The polycrystalline region 14by contains a polycrystalline metal nitride. For example, the polycrystalline region 14by contains titanium nitride.

The amorphous region 14bx is amorphous. The amorphous region 14bx contains an amorphous metal nitride. The chemical composition of the amorphous region 14bx is different from the chemical composition of the polycrystalline region 14by. The amorphous region 14bx contains molybdenum nitride, tungsten nitride, or tantalum nitride, for example.

The polycrystalline region 14by and the amorphous region 14bx can be formed by selecting an appropriate material and an appropriate formation condition.

With the transistor 201, as in the second embodiment, not only the grain size of the tungsten of the wiring part 30x but also the grain size of the tungsten of the contact part 30y is large. Therefore, the electrical resistance of the wiring layer 30 decreases, and the signal delay of the transistor 200 due to the wiring layer 30 is reduced, for example.

Note that whether the metal nitride layer 14b includes polycrystalline region 14by and the amorphous region 14bx can be determined with a transmission electron microscope, for example.

Thus, according to the variation of the second embodiment, a transistor 201 can be provided which is reduced in deterioration of the transistor characteristics, has a decreased on resistance, and is reduced in signal delay due to the wiring layer.

As described above, according to the second embodiment and the variation thereof, semiconductor devices with excellent transistor characteristics can be provided which are reduced in deterioration in transistor characteristics, have a decreased on resistance, and is reduced in signal delay due to the wiring layer.

### Third Embodiment

A semiconductor device according to a third embodiment differs from the semiconductor device according to the first embodiment in that a conductive layer includes a first layer and a second layer having a chemical composition different from the chemical composition of the first layer, the second layer is provided between the first layer and a metal nitride layer, and the second layer is amorphous and is in contact with the metal nitride layer. In the following, descriptions overlapping with the first embodiment may be omitted.

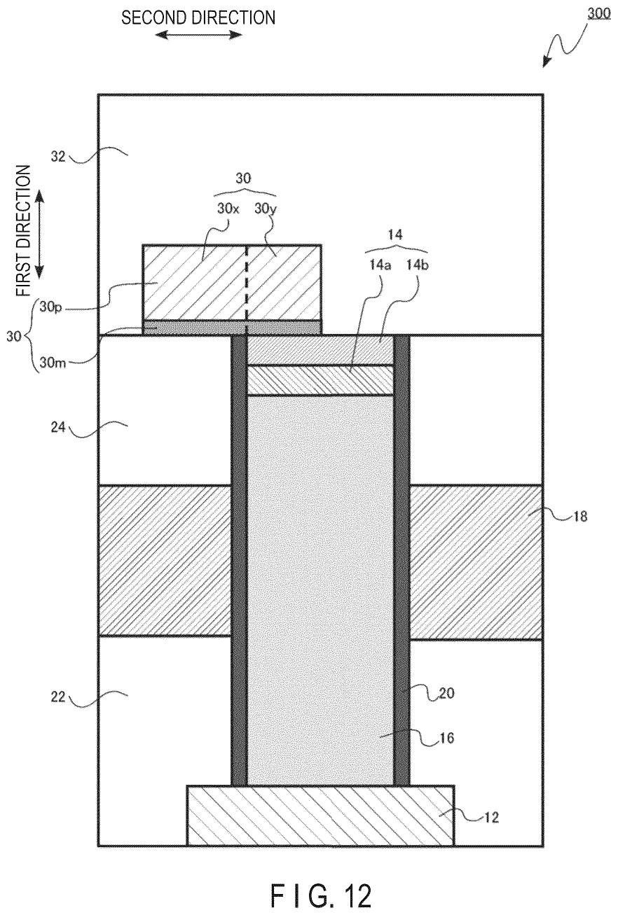

FIG. 12 is a schematic diagram showing the semiconductor device according to the third embodiment. FIG. 12 is a diagram corresponding to FIG. 1 showing the first embodiment.

The semiconductor device according to the third embodiment is a transistor 300. In the transistor 300, a wiring layer 30 includes a polycrystalline layer 30p and an amorphous layer 30m.

The polycrystalline layer 30p is an example of the first layer. The amorphous layer 30m is an example of the second layer.

The amorphous layer 30m is provided between the polycrystalline layer 30p and a metal nitride layer 14b.

The polycrystalline layer 30p is polycrystalline. For example, the polycrystalline layer 30p contains a polycrystalline metal or metal compound. For example, the polycrystalline layer 30p contains tungsten.

The amorphous layer 30m is amorphous. For example, the amorphous layer 30m contains an amorphous metal nitride. The chemical composition of the amorphous layer 30m is different from the chemical composition of the polycrystalline layer 30p. For example, the amorphous layer 30m contains molybdenum nitride, tungsten nitride, or tantalum nitride.

The polycrystalline layer 30p and the amorphous layer 30m can be formed by selecting an appropriate material and an appropriate formation condition.

With the transistor 300, when the polycrystalline layer 30p is formed by tungsten, for example, the layer under the layer of tungsten in the wiring part 30x and the layer under the layer of tungsten in the contact part 30y are the amorphous layer 30m. Therefore, the grain size of the tungsten of the wiring part 30x and the grain size of the tungsten of the contact part 30y are large. Therefore, the electrical resistance of the wiring layer 30 decreases, and the signal delay of the transistor 300 due to the wiring layer 30 is reduced, for example.

Thus, according to the third embodiment, a transistor 300 can be provided which is reduced in deterioration of the transistor characteristics, has a decreased on resistance, and is reduced in signal delay due to the wiring layer.

As described above, according to the third embodiment, a semiconductor device with excellent transistor characteristics can be provided which is reduced in deterioration of the transistor characteristics, has a decreased on resistance, and is reduced in signal delay due to the wiring layer.

### Fourth Embodiment

A semiconductor device according to a fourth embodiment differs from the semiconductor device according to the first embodiment in that, in the first cross section, a gate insulating layer surrounds an oxide conductor layer, the oxide conductor layer surrounds a metal nitride layer. In the following, descriptions overlapping with the first embodiment may be omitted.

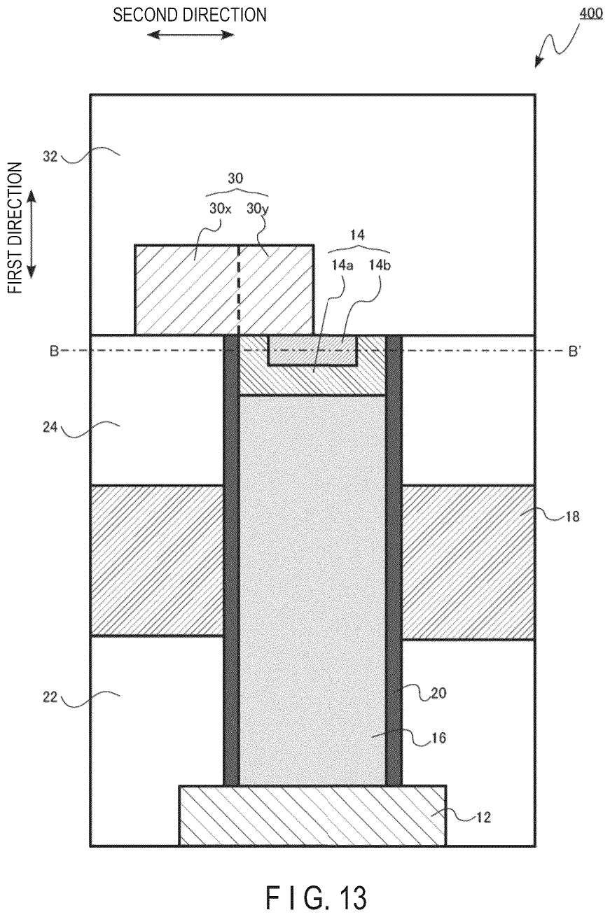

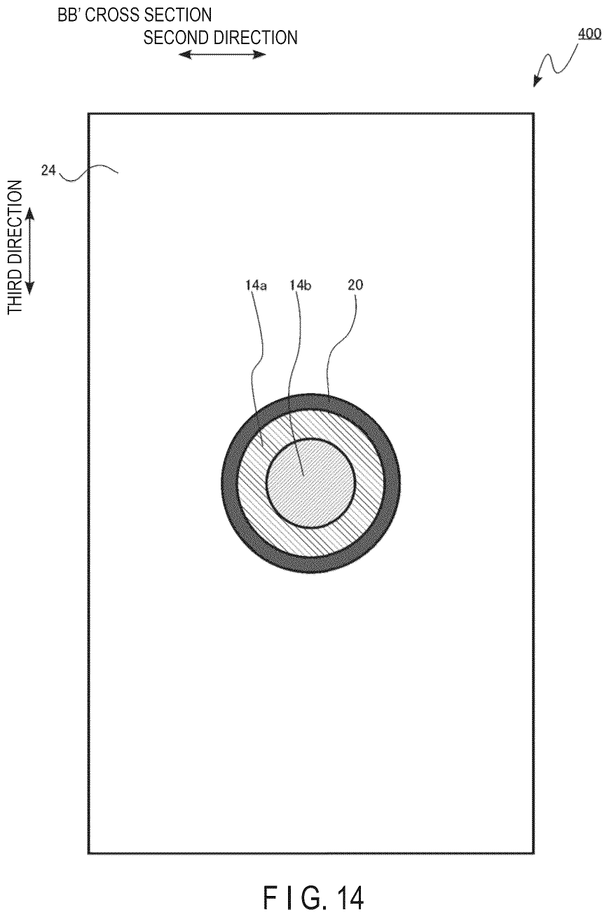

FIGS. 13 and 14 are schematic diagrams showing the semiconductor device according to the fourth embodiment. FIG. 13 is a diagram corresponding to FIG. 1 showing the first embodiment. FIG. 14 shows a cross section taken along the line BB′ in FIG. 13 (BB′ cross section). The BB′ cross section is an example of the first cross section.

The semiconductor device according to the fourth embodiment is a transistor 400. In the transistor 400, as shown in FIG. 14, in the first cross section that is perpendicular to the first direction and includes a metal nitride layer 14b, a gate insulating layer 20 surrounds an oxide conductor layer 14a, and the oxide conductor layer 14a surrounds the metal nitride layer 14b. The gate insulating layer 20 is in contact with the oxide conductor layer 14a, and the oxide conductor layer 14a is in contact with the metal nitride layer 14b.

According to the fourth embodiment, a transistor 400 can be provided which is reduced in deterioration of the transistor characteristics, has a decreased on resistance, and is reduced in signal delay due to the wiring layer.

As described above, according to the fourth embodiment, a semiconductor device with excellent transistor characteristics can be provided which is reduced in deterioration of the transistor characteristics, has a decreased on resistance, and is reduced in signal delay due to the wiring layer.

### Fifth Embodiment

A semiconductor device according to a fifth embodiment includes a first electrode, a second electrode, an oxide semiconductor layer provided between the first electrode and the second electrode, a gate electrode opposed to the oxide semiconductor layer, a gate insulating layer provided between the gate electrode and the oxide semiconductor layer, a conductive layer in contact with the second electrode, a first insulating layer provided on the gate electrode on a side facing the first electrode, a second insulating layer provided on the gate electrode on a side facing the second electrode, and a third insulating layer with the second insulating layer provided between the third insulating layer and the gate electrode. The second electrode includes a metal nitride layer in contact with the conductive layer and an oxide conductor layer that is provided between the metal nitride layer and the oxide semiconductor layer and is in contact with the oxide semiconductor layer. In a first cross section that is perpendicular to a first direction, which is a direction from the first electrode to the second electrode, and includes the oxide conductor layer, the gate insulating layer surrounds the oxide conductor layer. In a second cross section that is perpendicular to the first direction, is closer to the metal nitride layer than the first cross section, and includes the oxide conductor layer, the second insulating layer surrounds the oxide conductor layer and is in contact with the oxide conductor layer. The semiconductor device according to the fifth embodiment differs from the semiconductor device according to the first embodiment in that the gate insulating layer surrounds the oxide conductor layer in the first cross section that is perpendicular to the first direction from the first electrode to the second electrode and includes the oxide conductor layer, and the second insulating layer surrounds the oxide conductor layer and is in contact with the oxide conductor layer in the second cross section that is perpendicular to the first direction, is closer to the metal nitride layer than the first cross section, and includes the oxide conductor layer. In the following, descriptions overlapping with the first embodiment may be omitted.

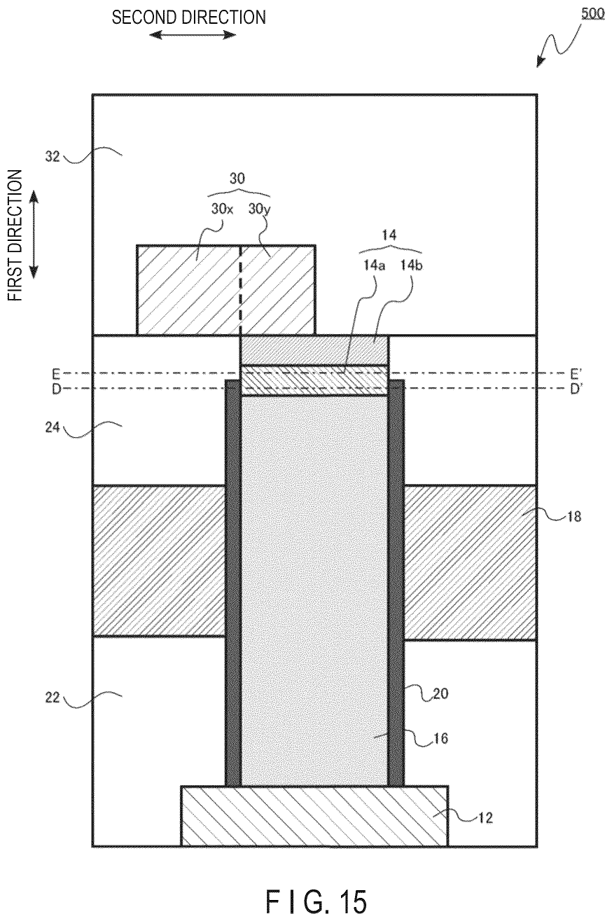

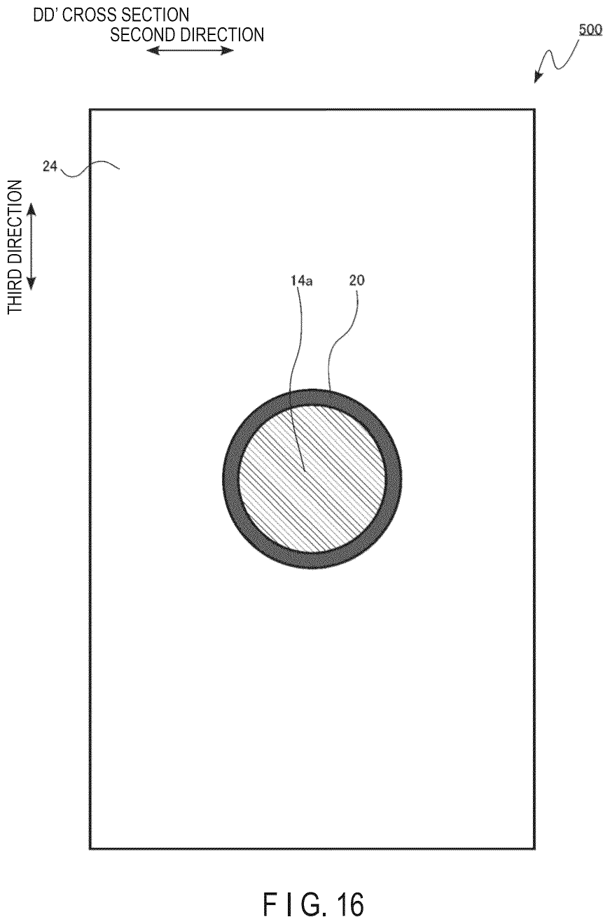

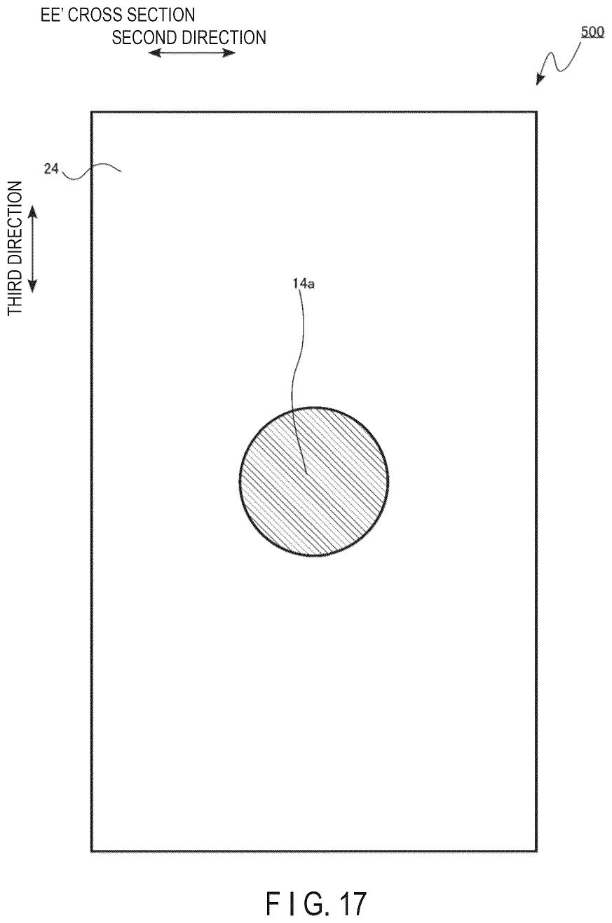

FIGS. 15, 16, and 17 are schematic diagrams showing the semiconductor device according to the fifth embodiment. FIG. 16 is a cross-sectional view taken along the line DD′ in FIG. 15 (DD′ cross section). FIG. 17 is a cross-sectional view taken along the line EE′ in FIG. 15 (EE′ cross section). FIG. 15 is a diagram corresponding to FIG. 1 showing the first embodiment.

In FIG. 15, the up-and-down direction is referred to as the first direction. In FIG. 15, the left-and-right direction is referred to as a second direction. The second direction is perpendicular to the first direction.

The DD′ cross section is an example of the first cross section. The EE′ cross section is an example of the second cross section.

The semiconductor device according to the fifth embodiment is a transistor 500.

In the transistor 500, as shown in FIG. 16, in the first cross section that is perpendicular to the first direction and includes an oxide conductor layer 14a, a gate insulating layer 20 surrounds the oxide conductor layer 14a. On the other hand, as shown in FIG. 17, in the second cross section that is perpendicular to the first direction, is closer to a metal nitride layer 14b than the first cross section, and includes the oxide conductor layer 14a, an upper insulating layer 24 surrounds the oxide conductor layer 14a and is in contact with the oxide conductor layer 14a.

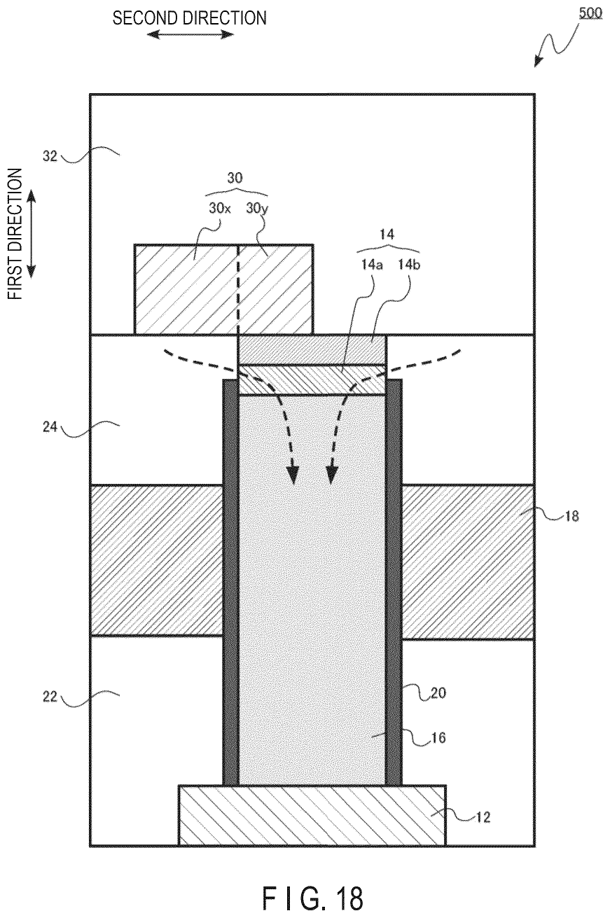

FIG. 18 is a diagram for illustrating an operation and an effect of the semiconductor device according to the fifth embodiment. FIG. 18 is a diagram corresponding to FIG. 15.

With an oxide semiconductor transistor, after the transistor structure is formed, the transistor may be subjected to a heat treatment in an atmosphere containing oxygen, in order to adjust the transistor characteristics. By supplying oxygen to an oxide semiconductor layer in which a channel is formed, for example, oxygen holes serving as donors are reduced to adjust the donor concentration. By adjusting the donor concentration, for example, the threshold voltage of the transistor is adjusted.

With the transistor 100 according to the first embodiment, for example, the upper electrode 14 is completely surrounded by the gate insulating layer 20. For example, the oxygen transmissibility of the gate insulating layer 20 is lower than the oxygen transmissibility of an interlayer insulating layer 32 or the oxygen transmissibility of the upper insulating layer 24. In particular, when the gate insulating layer 20 contains silicon nitride, the oxygen transmissibility of the gate insulating layer 20 is extremely low. Note that silicon nitride contains silicon (Si) and nitrogen (N).

Therefore, in a structure in which the upper electrode 14 is completely surrounded by the gate insulating layer 20, it may be difficult to supply oxygen to the oxide conductor layer 16 and thus to adjust the transistor characteristics.

In the transistor 500 according to the fifth embodiment, a part of the oxide conductor layer 14a is in contact with the upper insulating layer 24. In other words, there is a part where the gate insulating layer 20 does not exist between the upper insulating layer 24 and the oxide conductor layer 14a.

Therefore, when a heat treatment in an atmosphere containing oxygen is performed, oxygen can be supplied to the oxide semiconductor layer 16 through the part of the oxide conductor layer 14a that is in contact with the upper insulating layer 24, as shown by the dotted arrows in FIG. 18. Therefore, the transistor characteristics of the transistor 500 can be adjusted.

According to the fifth embodiment, a transistor 500 with excellent transistor characteristics can be provided which can be adjusted in transistor characteristics, is reduced in deterioration of the transistor characteristics, has a decreased on resistance, and is reduced in signal delay due to the wiring layer.

As described above, according to the fifth embodiment, a semiconductor device with excellent transistor characteristics can be provided which can be adjusted in transistor characteristics, is reduced in deterioration of the transistor characteristics, has a decreased on resistance, and is reduced in signal delay due to the wiring layer.

### Sixth Embodiment

A semiconductor device according to a sixth embodiment includes a first electrode, a second electrode, an oxide semiconductor layer provided between the first electrode and the second electrode, a gate electrode opposed to the oxide semiconductor layer, a gate insulating layer provided between the gate electrode and the oxide semiconductor layer, a conductive layer in contact with the second electrode, a first insulating layer provided on the gate electrode on a side facing the first electrode, a second insulating layer provided on the gate electrode on a side facing the second electrode, and a third insulating layer with the second insulating layer provided between the third insulating layer and the gate electrode. The second electrode includes a metal nitride layer in contact with the conductive layer and an oxide conductor layer that is provided between the metal nitride layer and the oxide semiconductor layer and is in contact with the oxide semiconductor layer. In a first cross section that is perpendicular to a first direction, which is a direction from the first electrode to the second electrode, and includes the oxide conductor layer, the second insulating layer surrounds the oxide semiconductor layer and is in contact with the oxide semiconductor layer. The semiconductor device according to the sixth embodiment differs from the semiconductor devices according to the first and fifth embodiments in that the second insulating layer surrounds the oxide conductor layer and in contact with the oxide semiconductor layer in the first cross section that is perpendicular to the first direction from the first electrode to the second electrode and includes the oxide conductor layer. In the following, descriptions overlapping with the first and fifth embodiments may be omitted.

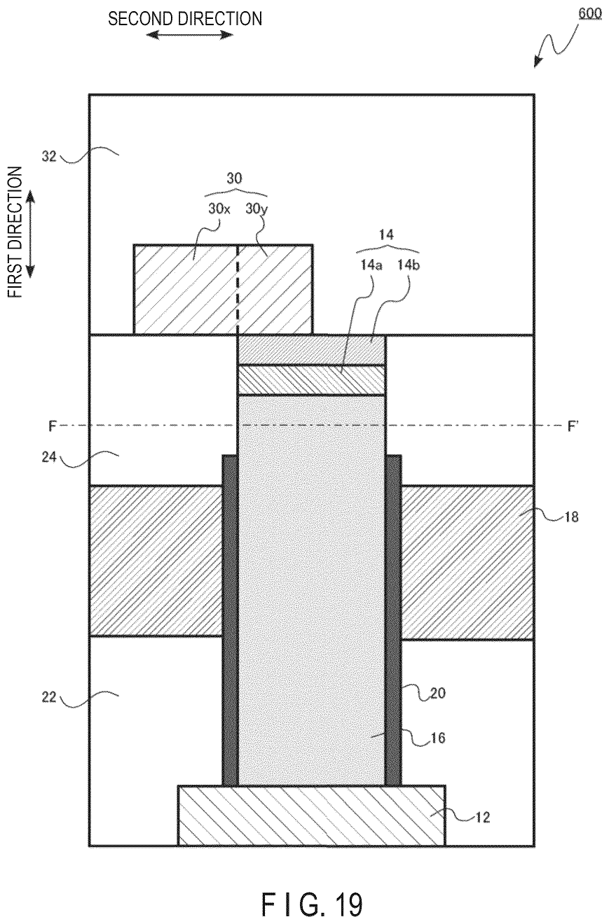

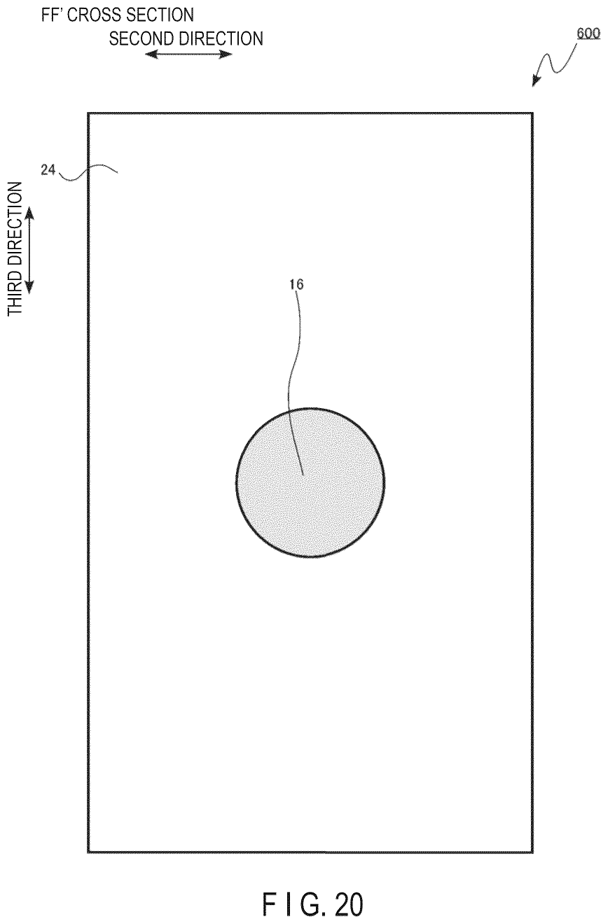

FIGS. 19 and 20 are schematic diagrams showing the semiconductor device according to the sixth embodiment. FIG. 20 is a cross-sectional view taken along the line FF′ in FIG. 19 (FF′ cross section). FIG. 19 is a diagram corresponding to FIG. 1 showing the first embodiment.

In FIG. 19, the up-and-down direction is referred to as the first direction. In FIG. 19, the left-and-right direction is referred to as a second direction. The second direction is perpendicular to the first direction.

The FF′ cross section is an example of the first cross section.

The semiconductor device according to the sixth embodiment is a transistor 600.

In the transistor 600, as shown in FIG. 20, in the first cross section that is perpendicular to the first direction and includes an oxide semiconductor layer 16, an upper insulating layer 24 surrounds the oxide semiconductor layer 16 and is in contact with the oxide semiconductor layer 16.

In the transistor 600, an upper electrode 14 is in contact with the upper insulating layer 24 in the second direction.

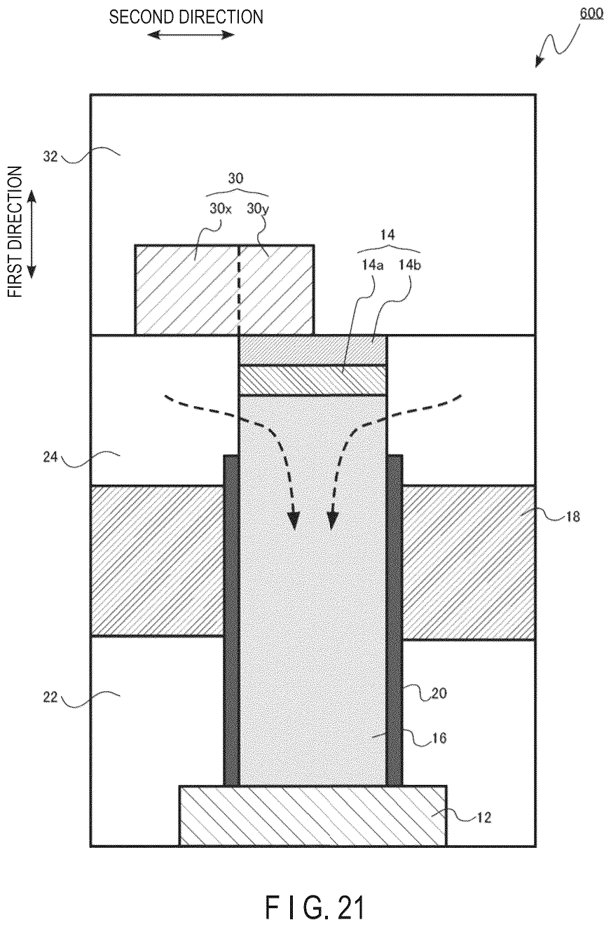

FIG. 21 is a diagram for illustrating an operation and an effect of the semiconductor device according to the sixth embodiment. FIG. 21 is a diagram corresponding to FIG. 19.

In the transistor 600 according to the sixth embodiment, a part of the oxide semiconductor layer 16 is in contact with the upper insulating layer 24. In other words, there is a part where the gate insulating layer 20 does not exist between the upper insulating layer 24 and the oxide semiconductor layer 16.

Therefore, when a heat treatment in an atmosphere containing oxygen is performed, oxygen can be supplied to the oxide semiconductor layer 16 through the part of the oxide semiconductor layer 16 that is in contact with the upper insulating layer 24, as shown by the dotted arrows in FIG. 21. Therefore, the transistor characteristics of the transistor 600 can be adjusted.

According to the sixth embodiment, a transistor 600 with excellent transistor characteristics can be provided which can be adjusted in transistor characteristics, is reduced in deterioration of the transistor characteristics, has a decreased on resistance, and is reduced in signal delay due to the wiring layer.

As described above, according to the sixth embodiment, a semiconductor device with excellent transistor characteristics can be provided which can be adjusted in transistor characteristics, is reduced in deterioration of transistor characteristics, has a decreased on resistance, and is reduced in signal delay due to the wiring layer.

### Seventh Embodiment

A semiconductor device according to a seventh embodiment differs from the semiconductor device according to the sixth embodiment in that an upper electrode is provided on a second insulating layer. In the following, descriptions overlapping with the sixth embodiment may be omitted.

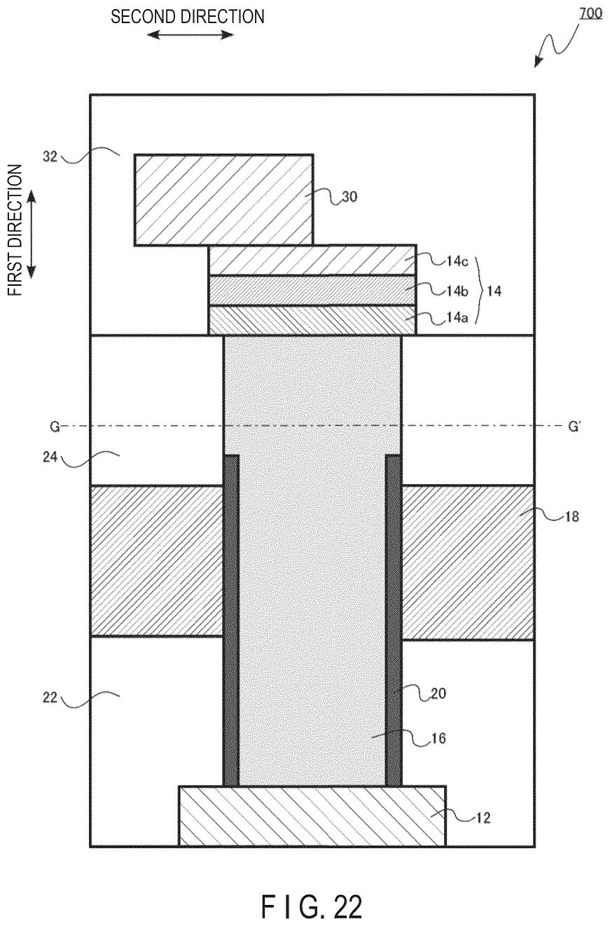

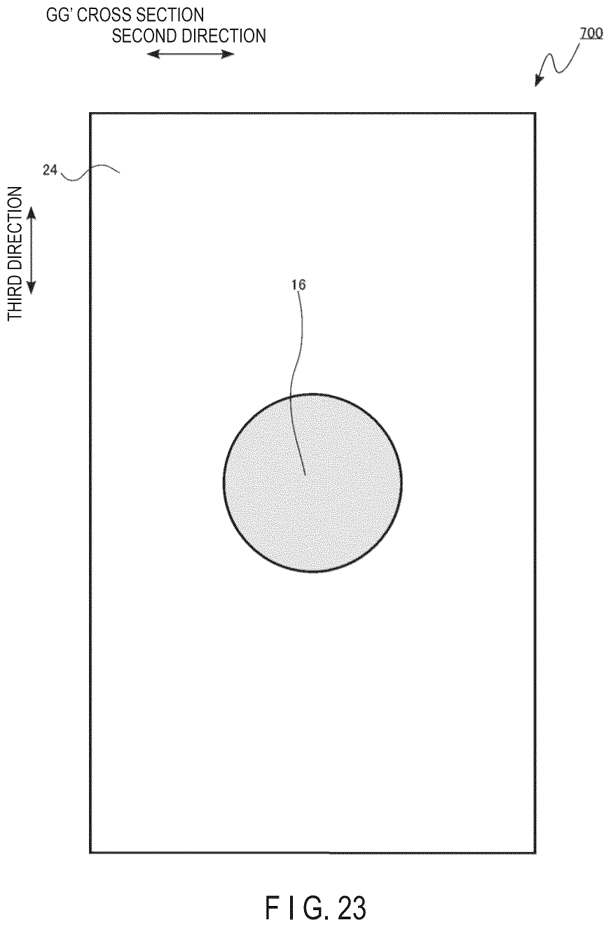

FIGS. 22 and 23 are schematic diagrams showing the semiconductor device according to the seventh embodiment. FIG. 23 is a cross-sectional view taken along the line GG′ in FIG. 22 (GG′ cross section). FIG. 22 is a diagram corresponding to FIG. 19 showing the sixth embodiment.

In FIG. 22, the up-and-down direction is referred to as a first direction. In FIG. 22, the left-and-right direction is referred to as a second direction. The second direction is perpendicular to the first direction. A direction perpendicular to the first direction and the second direction is referred to as a third direction.

The GG′ cross section is an example of a first cross section.

The semiconductor device according to the seventh embodiment is a transistor 700.

The transistor 700 includes a lower electrode 12, an upper electrode 14, an oxide semiconductor layer 16, a gate electrode 18, a gate insulating layer 20, a lower insulating layer 22, an upper insulating layer 24, an intermediate insulating layer 26, a wiring layer 30, and an interlayer insulating layer 32. The upper electrode 14 includes an oxide conductor layer 14a, a metal nitride layer 14b, and a metal layer 14c. The wiring layer 30 includes a wiring part 30x and a contact part 30y.

The upper electrode 14 is provided on the upper insulating layer 24. The interlayer insulating layer 32 is provided at the side of the upper electrode 14 in the second direction. The upper electrode 14 is in contact with the upper insulating layer 24 in the first direction. The upper electrode 14 is in contact with the interlayer insulating layer 32 in the second direction.

The metal nitride layer 14b is provided between the oxide conductor layer 14a and the metal layer 14c.

The metal layer 14c of the upper electrode 14 is formed by a conductor. For example, the metal layer 14c contains one metal element selected from among the group consisting of tungsten (W), molybdenum (Mo), copper (Cu), aluminum (Al), titanium (Ti), and tantalum (Ta).

The wiring layer 30 is in contact with the metal layer 14c. The wiring layer 30 extends in the third direction.

In the first direction of the transistor 700, the oxide semiconductor layer 16 exists between the gate insulating layer 20 and the upper electrode 14.

In the transistor 700, as shown in FIG. 23, in the first cross section, which is perpendicular to the first direction and includes the oxide semiconductor layer 16, the upper insulating layer 24 surrounds the oxide semiconductor layer 16 and is in contact with the oxide semiconductor layer 16.

In the transistor 700 according to the seventh embodiment, as with the transistor 600 according to the sixth embodiment, a part of the oxide semiconductor layer 16 is in contact with the upper insulating layer 24. In other words, there is a part where the gate insulating layer 20 does not exist between the upper insulating layer 24 and the oxide semiconductor layer 16.

Therefore, when a heat treatment in an atmosphere containing oxygen is performed, oxygen can be supplied to the oxide semiconductor layer 16 through the part of the oxide semiconductor layer 16 that is in contact with the upper insulating layer 24. Therefore, the transistor characteristics of the transistor 700 can be adjusted.

According to the seventh embodiment, a transistor 700 with excellent transistor characteristics can be provided which can be adjusted in transistor characteristics.

### Variation

A semiconductor device according to a variation of the seventh embodiment differs from the semiconductor device according to the seventh embodiment in that a second insulating layer exists between a gate insulating layer and an upper electrode in the first direction.

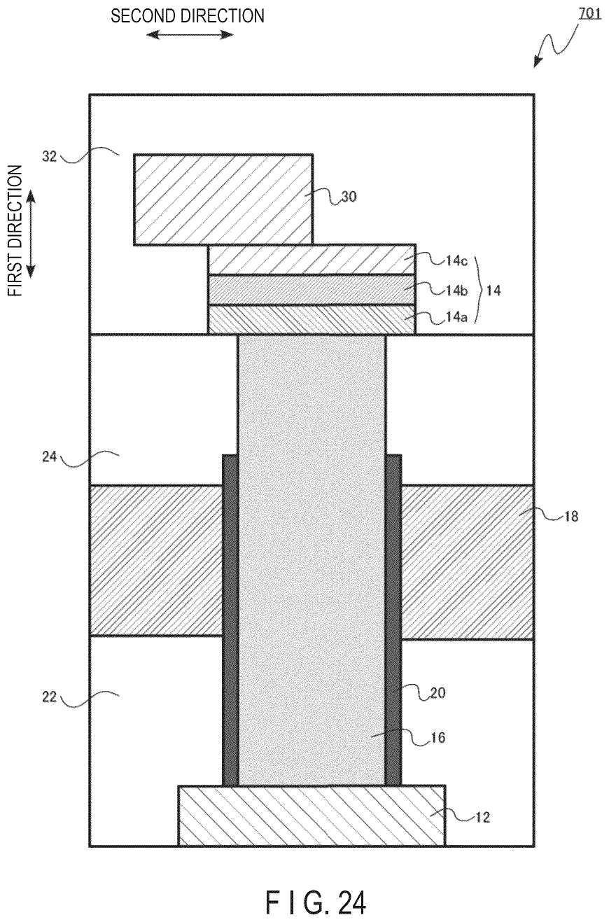

FIG. 24 is a schematic diagram showing the semiconductor device according to the variation of the seventh embodiment. FIG. 24 is a diagram corresponding to FIG. 22 showing the seventh embodiment.

The semiconductor device according to the variation of the seventh embodiment is a transistor 701.

In the first direction of the transistor 701, the upper insulating layer 24 exists between the gate insulating layer 20 and the upper electrode 14.

According to the variation of the seventh embodiment, a transistor 701 with excellent transistor characteristics can be provided which can be adjusted in transistor characteristics.

As described above, according to the variation of the seventh embodiment, a semiconductor device with excellent transistor characteristics can be provided which can be adjusted in transistor characteristics.

### Eighth Embodiment

A semiconductor device according to an eighth embodiment differs from the semiconductor device according to the seventh embodiment in that a first layer having an oxygen transmissibility lower than the oxygen transmissibility of a second insulating layer is provided between a gate electrode and the second insulating layer. In the following, descriptions overlapping with the seventh embodiment may be omitted.

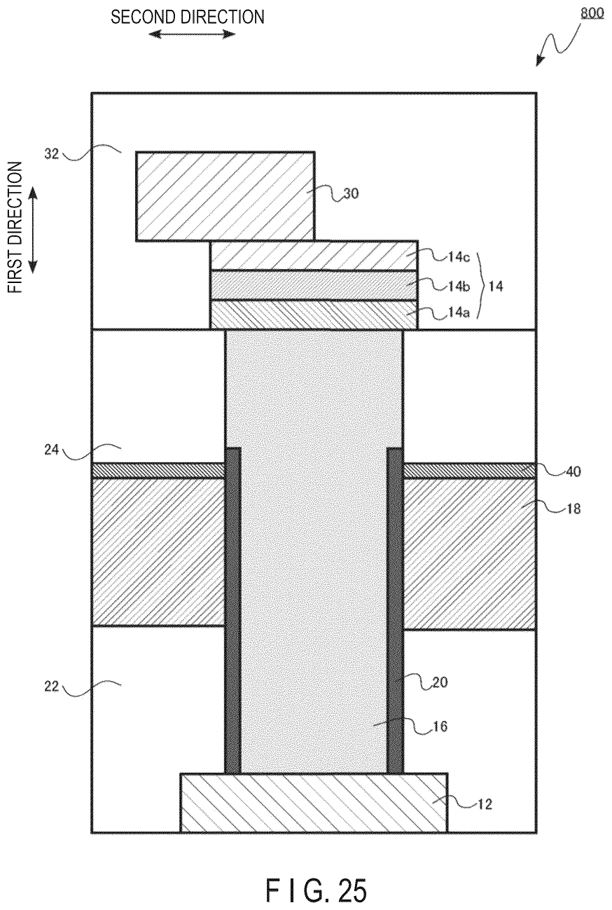

FIG. 25 is a schematic diagram showing the semiconductor device according to the eighth embodiment. FIG. 25 is a diagram corresponding to FIG. 22 showing the seventh embodiment.

In FIG. 25, the up-and-down direction is referred to as a first direction. In FIG. 22, the left-and-right direction is referred to as a second direction. The second direction is perpendicular to the first direction. A direction perpendicular to the first direction and the second direction is referred to as a third direction.

The semiconductor device according to the eighth embodiment is a transistor 800.

The transistor 800 includes a first oxygen blocking layer 40. The first oxygen blocking layer 40 is an example of the first layer.

The first oxygen blocking layer 40 is provided between a gate electrode 18 and an upper insulating layer 24. The oxygen transmissibility of the first oxygen blocking layer 40 is lower than the oxygen transmissibility of the upper insulating layer 24.

When the upper insulating layer 24 is formed by silicon oxide, for example, the first oxygen blocking layer 40 is formed by silicon nitride having a higher density than the silicon oxide of the upper insulating layer 24.

The first oxygen blocking layer 40 is formed by silicon nitride, for example.

For example, the first oxygen blocking layer 40 is a conductive nitride film. For example, the first oxygen blocking layer 40 is formed by titanium nitride, tungsten nitride, tantalum nitride, or molybdenum nitride.

In the transistor 800 according to the eighth embodiment, as with the transistor 700 according to the seventh embodiment, a part of the oxide semiconductor layer 16 is in contact with the upper insulating layer 24. In other words, there is a part where the gate insulating layer 20 does not exist between the upper insulating layer 24 and the oxide semiconductor layer 16.

Therefore, when a heat treatment in an atmosphere containing oxygen is performed, oxygen can be supplied to the oxide semiconductor layer 16 through the part of the oxide semiconductor layer 16 that is in contact with the upper insulating layer 24. Therefore, the transistor characteristics of the transistor 800 can be adjusted.

Since the transistor 800 according to the eighth embodiment includes the first oxygen blocking layer 40 having a lower oxygen transmissibility, oxidation of the gate electrode 18 is reduced when a heat treatment in an atmosphere containing oxygen is performed. Therefore, the increase of the resistance of the gate electrode 18 due to oxidation can be reduced.

According to the eighth embodiment, a transistor 800 with excellent transistor characteristics can be provided which can be adjusted in transistor characteristics and is reduced in increase of the electrical resistance of the gate electrode.

As described above, according to the eighth embodiment, a semiconductor device with excellent transistor characteristics can be provided which can be adjusted in transistor characteristics and is reduced in increase of the electrical resistance of the gate electrode.

### Ninth Embodiment

A semiconductor device according to a ninth embodiment differs from the semiconductor device according to the seventh embodiment in that the semiconductor device further includes a first layer having an oxygen transmissibility lower than the oxygen transmissibility of a third insulating layer, a second electrode further includes a metal layer, a metal nitride layer is provided between an oxide conductor layer and the metal layer, a third insulating layer is provided at the side of the oxide conductor layer, the metal nitride layer, and the metal layer in a second direction, which is perpendicular to a first direction, the first layer is provided between the oxide conductor layer, the metal nitride layer, and the metal layer and the third insulating layer and is in contact with the oxide conductor layer, the metal nitride layer, and the metal layer and the third insulating layer. In the following, descriptions overlapping with the seventh embodiment may be omitted.

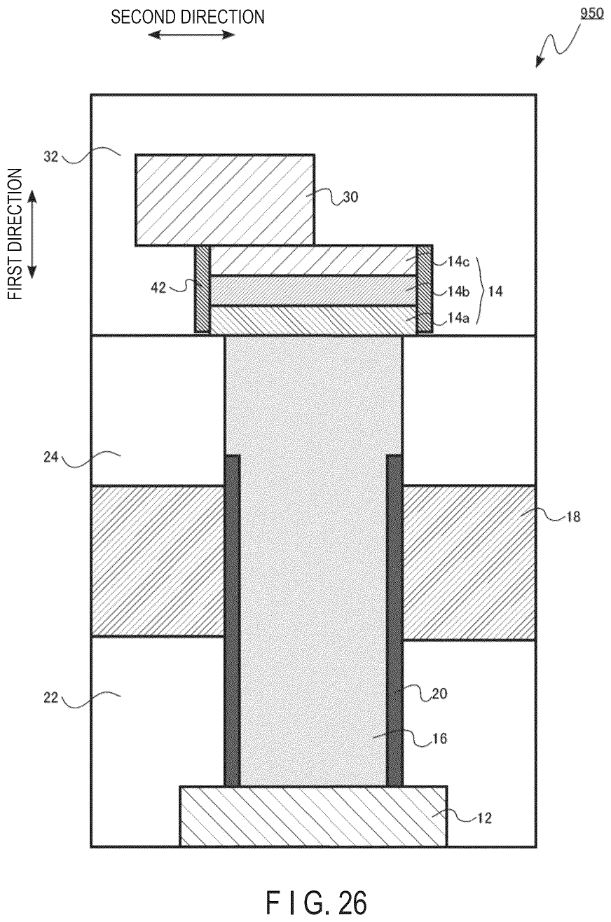

FIG. 26 is a schematic diagram showing the semiconductor device according to the ninth embodiment. FIG. 26 is a diagram corresponding to FIG. 22 showing the seventh embodiment.

In FIG. 26, the up-and-down direction is referred to as the first direction. In FIG. 26, the left-and-right direction is referred to as the second direction. The second direction is perpendicular to the first direction. A direction perpendicular to the first direction and the second direction is referred to as a third direction.

The semiconductor device according to the ninth embodiment is a transistor 950.

An upper electrode 14 of the transistor 950 includes an oxide conductor layer 14a, a metal nitride layer 14b, and a metal layer 14c. The metal nitride layer 14b is provided between the oxide conductor layer 14a and the metal layer 14c.

The interlayer insulating layer 32 is provided at the side of the upper electrode 14 in the second direction. The interlayer insulating layer 32 is provided at the side of the oxide conductor layer 14a, the metal nitride layer 14b, and the metal layer 14c in the second direction.

The transistor 950 includes a second oxygen blocking layer 42. The second oxygen blocking layer 40 is an example of the first layer.

The second oxygen blocking layer 42 is provided between the oxide conductor layer 14a, the metal nitride layer 14b, and the metal layer 14c and the interlayer insulating layer 32. The second oxygen blocking layer 42 is in contact with the oxide conductor layer 14a, the metal nitride layer 14b, and the metal layer 14c. The second oxygen blocking layer 42 is in contact with the interlayer insulating layer 32. The second oxygen blocking layer 42 is provided on a side surface of the upper electrode 14.

The oxygen transmissibility of the second oxygen blocking layer 42 is lower than the oxygen transmissibility of the interlayer insulating layer 32.

When the interlayer insulating layer 32 is formed by silicon oxide, for example, the second oxygen blocking layer 42 is formed by silicon oxide having a higher density than the silicon oxide of the interlayer insulating layer 32.

The second oxygen blocking layer 42 is formed by silicon nitride, for example.

For example, the second oxygen blocking layer 42 is a conductive nitride film. For example, the second oxygen blocking layer 42 is formed by titanium nitride, tungsten nitride, tantalum nitride, or molybdenum nitride.

In the transistor 950 according to the ninth embodiment, as with the transistor 700 according to the seventh embodiment, a part of the oxide semiconductor layer 16 is in contact with the upper insulating layer 24. In other words, there is a part where the gate insulating layer 20 does not exist between the upper insulating layer 24 and the oxide semiconductor layer 16.

Therefore, when a heat treatment in an atmosphere containing oxygen is performed, oxygen can be supplied to the oxide semiconductor layer 16 through the part of the oxide semiconductor layer 16 that is in contact with the upper insulating layer 24. Therefore, the transistor characteristics of the transistor 950 can be adjusted.

Since the transistor 950 according to the ninth embodiment includes the second oxygen blocking layer 42 having a lower oxygen transmissibility, oxidation of the upper electrode 14 is reduced when a heat treatment in an atmosphere containing oxygen is performed. Therefore, the increase in electrical resistance of the upper electrode 14 due to oxidation can be reduced.

In addition, diffusion of constituent elements of the oxide conductor layer 14a into the interlayer insulating layer 32 can be reduced, for example. Since the diffusion of constituent elements of the oxide conductor layer 14a into the interlayer insulating layer 32 is reduced, for example, the increase in electrical resistance of the upper electrode 14 can be reduced.

According to the ninth embodiment, a transistor 950 with excellent transistor characteristics can be provided which can be adjusted in transistor characteristics and is reduced in increase of the electrical resistance of the upper electrode.

As described above, according to the ninth embodiment, a semiconductor device with excellent transistor characteristics can be provided which can be adjusted in transistor characteristics and is reduced in increase of the electrical resistance of the upper electrode.

### Tenth Embodiment

A semiconductor storage device according to a tenth embodiment includes the semiconductor device according to the first embodiment and a capacitor electrically connected to the first electrode.

The semiconductor storage device according to the tenth embodiment is a semiconductor memory 1000. The semiconductor storage device according to the tenth embodiment is a DRAM. The semiconductor memory 1000 uses the transistor 100 according to the first embodiment as a switching transistor for a DRAM memory cell.

In the following, descriptions overlapping with the first embodiment may be omitted.

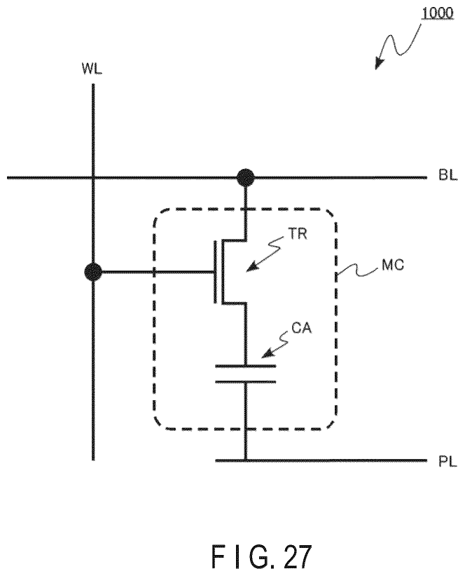

FIG. 27 is an equivalent circuit diagram showing the semiconductor storage device according to the tenth embodiment. Although FIG. 27 shows a case of one memory cell MC, a plurality of memory cells MC may be provided in an array, for example.

The semiconductor memory 1000 includes a memory cell MC, a word line WL, a bit line BL, and a plate line PL. The memory cell MC includes a switching transistor TR and a capacitor CA. In FIG. 27, the region enclosed by the dashed line is the memory cell MC.

The word line WL is electrically connected to the gate electrode of the switching transistor TR. The bit line BL is electrically connected to one of the source electrode and the grain electrode of the switching transistor TR. One electrode of the capacitor CA is electrically connected to the other of the source electrode and the drain electrode of the switching transistor TR. The other electrode of the capacitor CA is connected to the plate line PL.

The memory cell MC stores data by accumulating charge in the capacitor CA. Writing and reading of data is achieved by turning on the switching transistor TR.

For example, data writing to the memory cell MC is achieved by turning on the switching transistor TR in a state where a desired voltage is applied to the bit line BL.

Furthermore, for example, data reading from the memory cell MC is achieved by turning on the switching transistor TR and detecting a voltage change on the bit line BL that depends on the amount of charge accumulated in the capacitor.

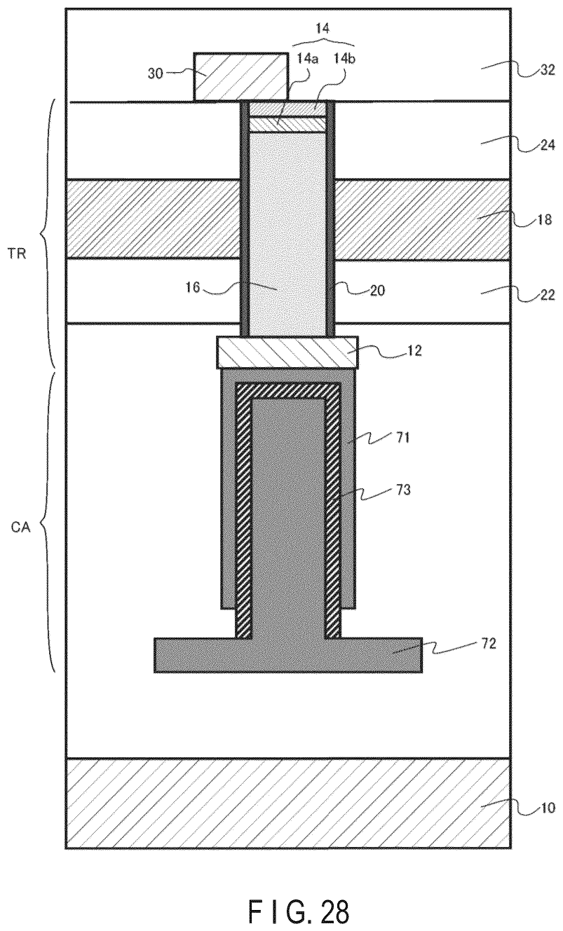

FIG. 28 is a schematic cross-sectional view of the semiconductor storage device according to the tenth embodiment. FIG. 28 shows a cross section of the memory cell MC of the semiconductor memory 1000.

The semiconductor memory 1000 includes a silicon substrate 10, the switching transistor TR, and the capacitor CA.

The switching transistor TR has the same structure as the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA includes a cell electrode 71, a plate electrode 72, and a capacitor insulating film 73. The cell electrode 71 is electrically connected to the lower electrode 12.

The cell electrode 71 and the plate electrode 72 are formed by titanium nitride, for example. The capacitor insulating film 73 has a stack structure of zirconium oxide, aluminum oxide, and zirconium oxide, for example.

The gate electrode 18 is the word line WL, for example. The wiring layer 30 is the bit line BL, for example. The plate electrode 72 is connected to the plate line PL, not shown, for example.

With the semiconductor memory 1000, an oxide semiconductor transistor having an extremely small channel leak current in the off state is used as the switching transistor TR. Therefore, a DRAM with excellent charge retention properties is provided.

In addition, the switching transistor TR of the semiconductor memory 1000 has excellent transistor characteristics. Therefore, a semiconductor memory 1000 with excellent operating characteristics can be provided.

In the tenth embodiment, a semiconductor memory that uses the transistor according to the first embodiment has been described as an example. However, the semiconductor memory according to the embodiment may be a semiconductor memory that uses the transistor according to the variation of the first embodiment, the transistor according to any of the second to ninth embodiments, or the transistor according to any of the variations of the embodiments.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The accompanying claims and their equivalents are intended to cover such forms or modification as would fall within the scope and spirit of the inventions.

What is claimed is:

1. A semiconductor device, comprising:
a first electrode;
a second electrode;
an oxide semiconductor layer between the first electrode and the second electrode;
a gate electrode opposed to the oxide semiconductor layer;
a gate insulating layer between the gate electrode and the oxide semiconductor layer;
a conductive layer in contact with the second electrode;
a first insulating layer on a side of the gate electrode that faces the first electrode;
a second insulating layer on a side of the gate electrode that faces the second electrode; and
a third insulating layer, the second insulating layer being between the third insulating layer and the gate electrode,
wherein the second electrode includes a metal nitride layer in contact with the conductive layer and an oxide conductor layer that is between the metal nitride layer and the oxide semiconductor layer and is in contact with the oxide semiconductor layer, and
wherein the gate insulating layer surrounds the metal nitride layer at a first cross section, the first cross section being taken along a plane perpendicular to a first direction, which is a direction from the first electrode to the second electrode, and the first cross section passes through the metal nitride layer.

2. The semiconductor device of claim 1, wherein:
the conductive layer includes a wiring part that is in contact with the second insulating layer in the first direction and a contact part that is in contact with the metal nitride layer in the first direction, and
a grain size of a first material contained in the wiring part is larger than a grain size of the first material contained in the contact part.

3. The semiconductor device of claim 2, wherein:
the second insulating layer is amorphous, and
the metal nitride layer is polycrystalline.

4. The semiconductor device of claim 1, wherein a part of the second electrode is in contact with the third insulating layer in the first direction.

5. The semiconductor device of claim 1, wherein the metal nitride layer includes an amorphous region, and the amorphous region is in contact with the conductive layer.

6. The semiconductor device of claim 1, wherein:
the metal nitride layer includes a first region and a second region, the second region having a chemical composition different from a chemical composition of the first region,
the first region is between the second region and the oxide conductor layer,
the second region is amorphous, and
the second region is in contact with the conductive layer.

7. The semiconductor device of claim 1, wherein:
the conductive layer includes a first layer and a second layer, the second layer having a chemical composition different from a chemical composition of the first layer,
the second layer is between the first layer and the metal nitride layer,
the second layer is amorphous, and
the second layer is in contact with the metal nitride layer.

8. The semiconductor device of claim 1, wherein, in the first cross section, the gate insulating layer surrounds the oxide conductor layer, and the oxide conductor layer surrounds the metal nitride layer.

9. The semiconductor device of claim 1, wherein, in a second cross section that is taken along a plane perpendicular to the first direction and that passes through the gate electrode, the gate electrode surrounds the oxide semiconductor layer.

10. A semiconductor device, comprising:
a first electrode;
a second electrode;
an oxide semiconductor layer between the first electrode and the second electrode;
a gate electrode opposed to the oxide semiconductor layer;
a gate insulating layer between the gate electrode and the oxide semiconductor layer;
a conductive layer in contact with the second electrode;
a first insulating layer on a side of the gate electrode that faces the first electrode;
a second insulating layer on a side of the gate electrode that faces the second electrode; and
a third insulating layer, the second insulating layer being between the third insulating layer and the gate electrode,
wherein the second electrode includes a metal nitride layer in contact with the conductive layer and an oxide conductor layer that is between the metal nitride layer and the oxide semiconductor layer and is in contact with the oxide semiconductor layer,
wherein, in a first cross section that is taken along a plane perpendicular to a first direction, which is a direction from the first electrode to the second electrode, and that passes through the oxide conductor layer, the gate insulating layer surrounds the oxide conductor layer, and
wherein, in a second cross section that is taken along a plane perpendicular to the first direction, is closer to the metal nitride layer than the first cross section, and that passes through the oxide conductor layer, the second insulating layer surrounds the oxide conductor layer, and the second insulating layer is in contact with the oxide conductor layer.

11. The semiconductor device of claim 10, wherein the gate insulating layer contains silicon and nitrogen.

12. The semiconductor device of claim 10, wherein:
the conductive layer includes a wiring part that is in contact with the second insulating layer in the first direction and a contact part that is in contact with the metal nitride layer in the first direction, and
a grain size of a first material contained in the wiring part is larger than a grain size of the first material contained in the contact part.

13. The semiconductor device of claim 12, wherein the second insulating layer is amorphous, and the metal nitride layer is polycrystalline.

14. A semiconductor device, comprising:
a first electrode;
a second electrode;
an oxide semiconductor layer between the first electrode and the second electrode;
a gate electrode opposed to the oxide semiconductor layer;
a gate insulating layer between the gate electrode and the oxide semiconductor layer;
a conductive layer in contact with the second electrode;
a first insulating layer on a side of the gate electrode that faces the first electrode;
a second insulating layer on a side of the gate electrode that faces the second electrode; and
a third insulating layer, the second insulating layer being between the third insulating layer and the gate electrode,
wherein the second electrode includes a metal nitride layer in contact with the conductive layer and an oxide conductor layer that is between the metal nitride layer and the oxide semiconductor layer and is in contact with the oxide semiconductor layer, and
wherein, in a first cross section that is taken along a plane perpendicular to a first direction, which is a direction from the first electrode to the second electrode, and that passes through the oxide conductor layer, the second insulating layer surrounds the oxide semiconductor layer, and the second insulating layer is in contact with the oxide semiconductor layer.

15. The semiconductor device of claim 14, wherein the gate insulating layer contains silicon and nitrogen.

16. The semiconductor device of claim 14, wherein the second electrode is in contact with the second insulating layer in a second direction perpendicular to the first direction.

17. The semiconductor device of claim 14, wherein:
the second electrode is in contact with the second insulating layer in the first direction, and
the second electrode is in contact with the third insulating layer in a second direction perpendicular to the first direction.

18. The semiconductor device of claim 14, further comprising a first layer between the gate electrode and the second insulating layer, the first layer having an oxygen transmissibility lower than an oxygen transmissibility of the second insulating layer.

19. The semiconductor device of claim 14, further comprising a first layer having an oxygen transmissibility lower than an oxygen transmissibility of the third insulating layer,
wherein:
the second electrode further includes a metal layer,
the metal nitride layer is between the oxide conductor layer and the metal layer,
the third insulating layer is at a side of the oxide conductor layer, the metal nitride layer and the metal layer in a second direction perpendicular to the first direction, and
the first layer is between the oxide conductor layer, the metal nitride layer and the metal layer and the third insulating layer, and is in contact with the oxide conductor layer, the metal nitride layer, the metal layer and the third insulating layer.

20. A semiconductor device, comprising:
the semiconductor device of claim 1; and
a capacitor connected to the first electrode.

21. A semiconductor storage device, comprising:
the semiconductor device of claim 10; and
a capacitor connected to the first electrode.

22. A semiconductor storage device, comprising:
the semiconductor device of claim 14; and
a capacitor connected to the first electrode.
